(19) United States
(12) Patent Application Publication
(10) Pub. No.: US 2013/0325375 A1
(43) Pub. Date: Dec. 5, 2013

(54) MONITORING DEVICE, INFORMATION PROCESSING APPARATUS, AND MONITORING METHOD

(71) Applicant: FUJITSU LIMITED, Kawasaki-shi (JP)

(72) Inventor: Ayumi INOBE, Kawasaki (JP)

(73) Assignee: FUJITSU LIMITED, Kawasaki-shi (JP)

(21) Appl. No.: 13/847,635

(22) Filed: Mar. 20, 2013

(30) Foreign Application Priority Data
May 30, 2012 (JP) 2012-123346

(51) Int. Cl. G01R 31/08

(52) U.S. Cl. CPC G01R 31/088
USPC 702/59

(57) ABSTRACT

A monitoring device includes a holding circuit and a processor configured to give priority to a first failure over a second failure when the holding circuit holds the first failure and identify a first suspected portion in which the first failure has occurred. The first failure is a failure detected in a first power supply unit and the second failure is a failure detected at least either in a device or in a second power supply unit that converts power supplied from the first power supply unit and that supplies resultant power to the device.

### CROSS-REFERENCE TO RELATED APPLICATION

This application is based upon and claims the benefit of priority of the prior Japanese Patent Application No. 2012-123346, filed on May 30, 2012, the entire contents of which are incorporated herein by reference.

### FIELD

The embodiments discussed herein are related to a monitoring device, an information processing apparatus, and a monitoring method.

### BACKGROUND

In a computer system (information processing apparatus) including a plurality of devices, a power supply system for the devices is hierarchized. For example, one or more AC-DC conversion units that convert alternating current from an alternating-current power supply into direct current are mounted on the computer system as power supply units at high levels. In addition, a plurality of DC-DC conversion units that convert the direct current from the one or more AC-DC conversion units and that supply resultant direct current to the devices are mounted on the computer system as power supply units at low levels.

In such a hierarchized power supply system, if a failure occurs in a power supply unit at a high level, failures caused by this failure occur in power supply units and devices at low levels. At this time, one of the failures that have occurred in the power supply units and the devices at the low levels might be detected before the failure that has occurred in the power supply unit at the high level is detected. Because the order of occurrence (order of detection) of failures changes depending on variation in the characteristics of each power supply unit and the usage load of each device, the order is not assured. Therefore, a failure at a high level might be transmitted to a monitoring processing unit after a failure at a low level is transmitted to the monitoring processing unit, or a failure at a low level and a failure at a higher level might be simultaneously transmitted to the monitoring processing unit.

If the monitoring processing unit that has received failures sequentially processes the received failures and generates log information for each failure in order of reception, it undesirably looks as if a plurality of failures have occurred in the computer system. Accordingly, it becomes difficult for the monitoring processing unit to identify a power supply unit at a highest level that has caused a series of failures this time as a suspected portion, and the stable operation of the power supply system and accordingly the stable operation of the computer system are not assured.

Therefore, the monitoring processing unit logs only information regarding a failure that has occurred in a power supply unit or a device at a highest level among the series of failures transmitted thereto during a certain period of time since a failure was transmitted thereto for the first time. The monitoring processing unit then identifies the power supply unit or the device at the highest level as a suspected portion that has caused the series of failures this time on the basis of the logged information. The certain period of time is time assumed to be taken until a plurality of failures relating to a certain failure are transmitted after the certain failure is transmitted. In other words, in consideration of detection of failures at low levels that may occur during the certain period of time before and after detection of a failure at a high level, the monitoring processing unit logs only a failure at a highest level among power supply units and devices in which failures have been detected, and identifies a portion in which the logged failure has occurred as a suspected portion.

In recent computer systems, devices to be mounted have been becoming diversified and the number of devices mounted have been increasing. Accordingly, the number of power supply units (AC-DC conversion units and DC-DC conversion units) mounted to supply power to a large number of devices has also been increasing. Thus, when the numbers of DC-DC conversion units and devices mounted have increased and an AC-DC conversion unit that supplies power to the DC-DC conversion units also supplies power to the monitoring processing unit, the following problem may arise.

If a failure occurs in an AC-DC conversion unit at a high level, DC-DC conversion units and devices at low levels transmit a large number of failures to the monitoring processing unit in the certain period of time. Therefore, even if a failure occurs in the AC-DC conversion unit during the certain period of time, it is difficult to identify the AC-DC conversion unit as a suspected portion because supply of power to the monitoring processing unit stops while the monitoring processing unit is processing the failures of the DC-DC conversion units and the devices.

Japanese Laid-open Patent Publication No. 2008-71201, Japanese Examined Utility Model Registration Application Publication No. 3-14923, and Japanese Laid-open Patent Publication No. 4-125716 are known as examples of the related art.

### SUMMARY

According to an aspect of the invention, a monitoring device includes a holding circuit; and a processor configured to give priority to a first failure over a second failure when the holding circuit holds the first failure and identify a first suspected portion in which the first failure has occurred. The first failure is a failure detected in a first power supply unit and the second failure is a failure detected at least either in a device or in a second power supply unit that converts power supplied from the first power supply unit and that supplies resultant power to the device.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a block diagram illustrating the configuration of an information processing apparatus including a monitoring device according to a first embodiment;

FIG. 2 is a flowchart illustrating a monitoring processing procedure performed by a processing unit of the monitoring device illustrated in FIG. 1;

FIG. 3 is a block diagram illustrating the configuration of an information processing apparatus including a monitoring device according to a second embodiment;

FIG. 4 is a flowchart illustrating a monitoring processing procedure performed by a processing unit of the monitoring device illustrated in FIG. 3;

FIG. 5 is a diagram illustrating an example of a suspected portion identification table used by a monitoring device according to a third embodiment;

FIG. 6 is a block diagram illustrating the configuration of an information processing apparatus including the monitoring device according to the third embodiment;

FIG. 7 is a flowchart illustrating a monitoring processing procedure performed by a processing unit of the monitoring device illustrated in FIG. 6;

FIG. 8 is a block diagram illustrating the configuration of an information processing apparatus including a monitoring device according to a fourth embodiment;

FIG. 9 is a flowchart illustrating a monitoring processing procedure performed by a processing unit of the monitoring device illustrated in FIG. 8;

FIG. 10 is a block diagram illustrating the configuration of a power supply system and the configuration of a monitoring device for the power supply system;

FIG. 11 is a flowchart illustrating a monitoring processing procedure performed by a processing unit of the monitoring device illustrated in FIG. 10; and

FIG. 12 is a diagram illustrating an example of a suspected portion identification table.

### DESCRIPTION OF EMBODIMENTS

Embodiments will be described hereinafter with reference to the drawings.

### [1] Monitoring Device for Power Supply System of Information

### Processing Apparatus

[1-1] Configurations of Power Supply System and Monitoring Device for Power Supply System

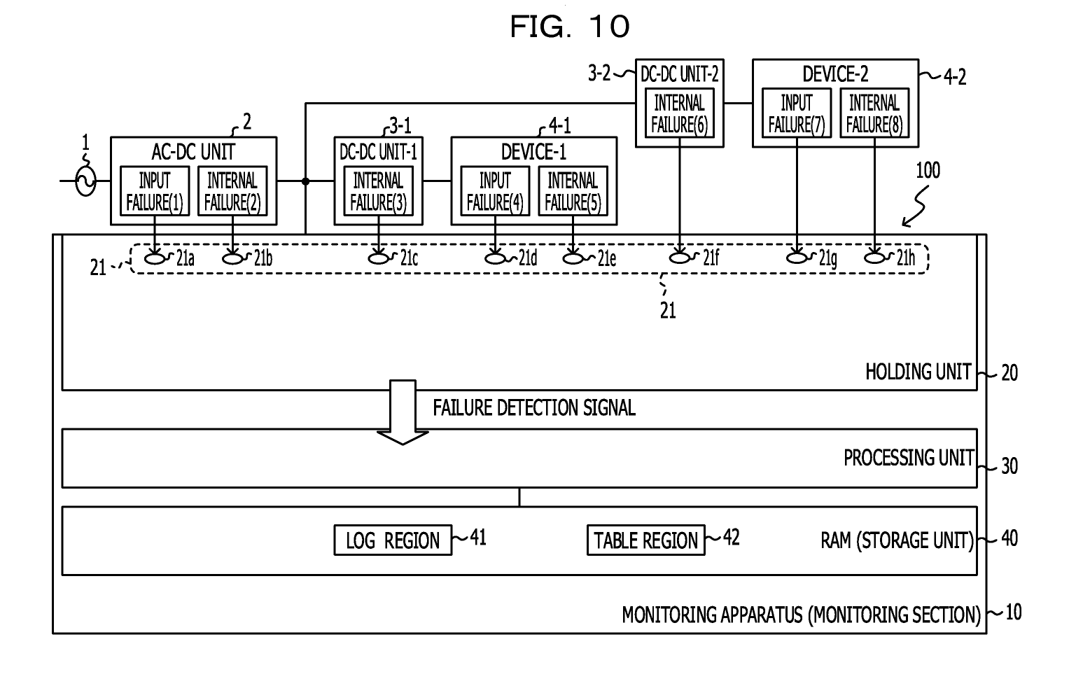

First, a technology (a power supply system and a monitoring device for the power supply system) that serves as a precondition for the embodiments (first to fourth embodiments) will be described with reference to FIG. 10. FIG. 10 is a block diagram illustrating the configuration of the power supply system and the configuration of a monitoring device 10 for the power supply system.

As illustrated in FIG. 10, in an information processing apparatus (computer system) 100 including a plurality of (two in the figure) devices 4-1 and 4-2, the power supply system for the devices 4-1 and 4-2 is hierarchized. In the example illustrated in FIG. 10, an AC-DC conversion unit 2 that converts alternating current from an alternating-current power supply 1 into direct current is mounted as a power supply unit (first power supply unit) at a high level. In addition, a plurality of (two in the figure) DC-DC conversion units 3-1 and 3-2 that convert the direct current from the AC-DC conversion unit 2 and that supply resultant direct current to the devices 4-1 and 4-2, respectively, are mounted as power supply units (second power supply units) at a low level. A reference numeral 4-1 or 4-2 is used for specifying one of the two devices, whereas a reference numeral 4 is used for referring to an arbitrary device. Similarly, a reference numeral 3-1 or 3-2 is used for specifying one of the two DC-DC conversion units, whereas a reference numeral 3 is used for referring to an arbitrary DC-DC conversion unit. In the drawings, the AC-DC conversion unit 2 is denoted by “AC-DC unit”, the DC-DC conversion units 3-1 and 3-2 are denoted by “DC-DC unit-1” and “DC-DC unit-2”, respectively, and the devices 4-1 and 4-2 are denoted by “device-1” and “device-2”, respectively.

The monitoring device (monitoring section) 10 that monitors the AC-DC conversion unit 2, the DC-DC conversion units 3, and the devices 4 for failures includes a holding unit 20, a processing unit (monitoring processing unit) 30, and a random-access memory (RAM; a storage unit) 40.

The holding unit 20 includes a failure holding register 21 that receives and holds failure signals transmitted from the units 2 and 3 and the devices 4. The failure holding register 21 holds a failure until the processing unit 30 completes processing. The holding unit 20 is an example of a holding circuit. The failure holding register 21 is an example of a storage.

Here, the AC-DC conversion unit 2, the DC-DC conversion units 3, and the devices 4 have a function of transmitting failure signals to the monitoring device 10 upon detecting failures that have occurred therein, respectively.

The AC-DC conversion unit 2 can detect an input failure (1) and an internal failure (2), and transmits a failure signal to the holding unit 20 upon detecting the input failure (1) or the internal failure (2). Upon receiving a failure signal regarding the input failure (1), the holding unit 20 switches, in the failure holding register 21, the value of a bit 21a, which corresponds to the input failure (1), from 0 to 1. Upon receiving a failure signal regarding the internal failure (2), the holding unit 20 switches, in the failure holding register 21, the value of a bit 21b, which corresponds to the internal failure (2), from 0 to 1.

The DC-DC conversion unit 3-1 can detect an internal failure (3), and transmits a failure signal to the holding unit 20 upon detecting the internal failure (3). Upon receiving the failure signal regarding the internal failure (3), the holding unit 20 switches, in the failure holding register 21, the value of a bit 21c, which corresponds to the internal failure (3), from 0 to 1. Similarly, the DC-DC conversion unit 3-2 can detect an internal failure (6), and transmits a failure signal to the holding unit 20 upon detecting the internal failure (6). Upon receiving the failure signal regarding the internal failure (6), the holding unit 20 switches, in the failure holding register 21, the value of a bit 21f, which corresponds to the internal failure (6), from 0 to 1. Although the DC-DC conversion units 3 detect the internal failures (3) and (6), the DC-DC conversion units 3 may be configured in such a way as to detect input failures.

The device 4-1 can detect an input failure (4) and an internal failure (5), and transmits a failure signal to the holding unit 20 upon detecting the input failure (4) or the internal failure (5). Upon receiving a failure signal regarding the input failure (4), the holding unit 20 switches, in the failure holding register 21, the value of a bit 21d, which corresponds to the input failure (4), from 0 to 1. Upon receiving a failure signal regarding the internal failure (5), the holding unit 20 switches, in the failure holding register 21, the value of a bit 21e, which corresponds to the internal failure (5), from 0 to 1.

Similarly, the device 4-2 can detect an input failure (7) and an internal failure (8), and transmits a failure signal to the holding unit 20 upon detecting the input failure (7) or the internal failure (8). Upon receiving a failure signal regarding the input failure (7), the holding unit 20 switches, in the failure holding register 21, the value of a bit 21g, which corresponds to the input failure (7), from 0 to 1. Upon receiving a failure signal regarding the internal failure (8), the holding unit 20 switches, in the failure holding register 21, the value of a bit 21h, which corresponds to the internal failure (8), from 0 to 1.

The holding unit 20 regularly, or in accordance with an interrupt signal, generates a logical sum of the values of the bits 21a to 21h as a failure detection signal and transmits the failure detection signal to the processing unit 30, in order to notify the processing unit 30 of occurrence of a failure in the power supply system. That is, when at least one of the bits 21a to 21h is 1, the holding unit 20 continues to transmit the failure detection signal to the processing unit 30 until the processing unit 30 completes a process for identifying a suspected portion and resets all failures held by the failure holding register 21 (resets all the values of the bits 21a to 21h to 0).

The processing unit 30 identifies the unit 2 or 3 or the device 4 in which a failure has occurred on the basis of a failure held by the holding unit 20 and a suspected portion identification table (described later) held by the RAM 40. The processing unit 30 includes a timer (not illustrated in FIG. 10) that begins to measure a certain period of time upon receiving a failure detection signal from the holding unit 20. As described above, the certain period of time is time assumed to be taken until all of one or more failures relating to a certain failure are transmitted after the certain failure is transmitted (after a failure detection signal is received). In consideration of detection of failures at lower levels that may occur during the certain period of time before and after detection of a failure at a high level, the processing unit 30 logs, in a log region 41 of the RAM 40, only a failure at a highest level among the units 2 and 3 and the devices 4 in which failures have been detected, and identifies a portion in which the logged failure has occurred as a suspected portion.

The processing unit 30 provides individual failures held by the failure holding register 21 (the bits 21a to 21h) of the holding unit 20 with unique alarm numbers. Upon receiving a failure detection signal from the holding unit 20, the processing unit 30 replaces a failure held by the failure holding register 21 with an alarm number, and executes the process for identifying a suspected portion.

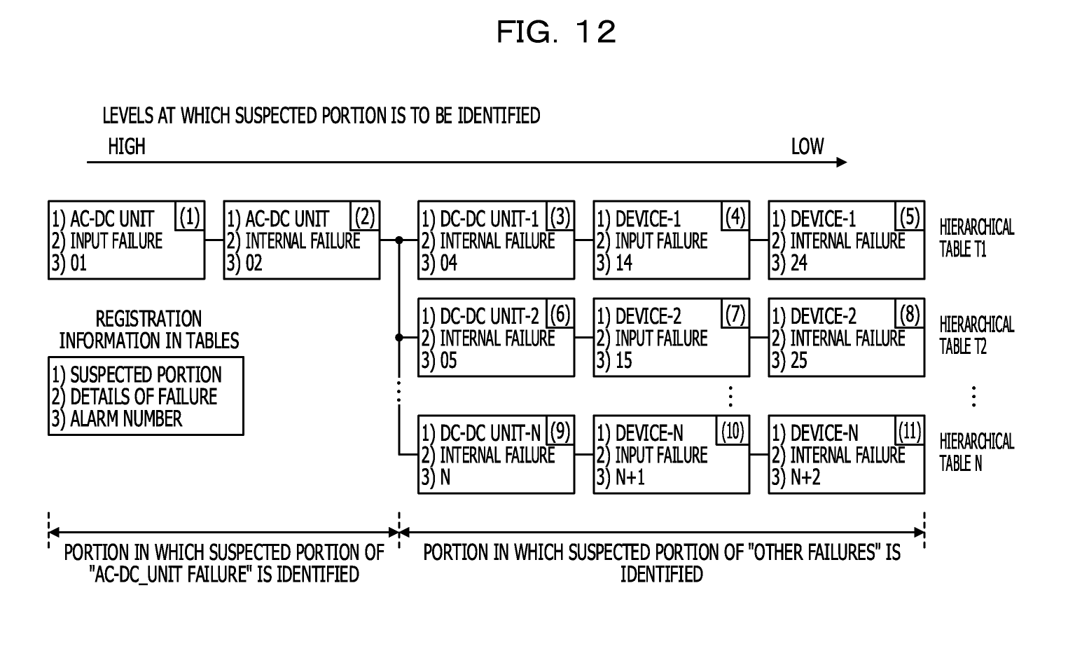

Now, FIG. 12 illustrates an example of the suspected portion identification table used by the processing unit 30 to execute the process for identifying a suspected portion. The suspected portion identification table is generated by the processing unit 30 and saved to a table region 42 of the RAM 40 in advance. The suspected portion identification table illustrated in FIG. 12 is an array table that includes N hierarchical tables T1 to TN and that hierarchically represents registered information regarding failures (1) to (11) transmitted from the units 2 and 3 and the devices 4 in accordance with the hierarchy of the power supply system of the computer system 100. The failures (1) to (8) illustrated in FIG. 12 correspond to the failures (1) to (8), respectively, illustrated in FIG. 10, and the table illustrated in FIG. 12 also defines the registered information regarding the failures (9) to (11), which are not illustrated in FIG. 10.

In the hierarchical table T1, the registered information regarding the hierarchically successive failures (1) to (5) is arranged in a hierarchical order. In the hierarchical table T2, the registered information regarding the hierarchically successive failures (1), (2), and (6) to (8) is arranged in a hierarchical order. In the hierarchical table TN, the registered information regarding the hierarchically successive failures (1), (2), and (9) to (11) is arranged in a hierarchical order.

The registered information regarding the failures (1) to (11) in the suspected portion identification table includes 1) suspected portion, 2) details of failure, and 3) alarm number.

In FIG. 12, if the portion in which a failure has occurred is the AC-DC conversion unit 2, “AC-DC unit” is registered to 1) suspected portion. If the portion in which a failure has occurred is the DC-DC conversion unit 3-1, “DC-DC unit-1” is registered to 1) suspected portion, and if the portion in which a failure has occurred is the DC-DC conversion unit 3-2, “DC-DC unit-2” is registered to 1) suspected portion. If the portion in which a failure has occurred is the device 4-1, “device-1” is registered to 1) suspected portion, and if the portion in which a failure has occurred is the device 4-2, “device-2” is registered to 1) suspected portion.

In FIG. 12, “input failure” or “internal failure” is registered to 2) details of failure.

In FIG. 12, 01, 02, 04, 14, 24, 05, 15, 25, N, N+1, and N+2 provided for the failures (1) to (11), respectively, are registered to 3) alarm number.

[1-2] Operation of Monitoring Device (Process for Identifying Suspected Portion)

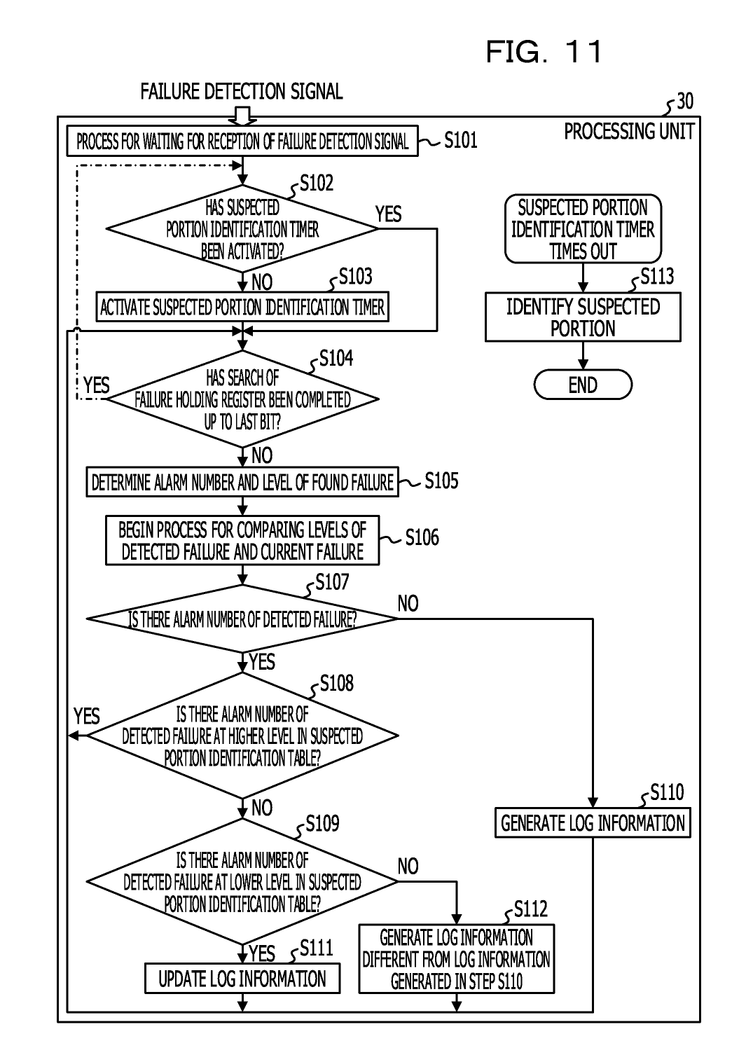

Next, the process for identifying a suspected portion executed by the processing unit 30 after the processing unit 30 receives a failure detection signal from the holding unit 20 will be described in detail with reference to a flowchart (steps S101 to S113) of FIG. 11.

In the initial state of the monitoring device 10, 0 is set to the bits 21a to 21h of the failure holding register 21, and the timer (suspected portion identification timer) that measures a period of time (the above-described period of time) in which the suspected portion is identified has not been activated. All log information in the log region 41 of the RAM 40 has been deleted.

The processing unit 30 continuously waits for a signal transmitted from the holding unit 20 (step S101).

Since the suspected portion identification timer has not been activated (the NO route in step S102) when the processing unit 30 has received a failure detection signal from the holding unit 20 for the first time, the processing unit 30 activates the suspected portion identification timer (step S103), and proceeds to processing in step S104. If the suspected portion identification timer has already been activated (the YES route in step S102), the processing unit 30 proceeds to the processing in step S104 without performing the processing in step S103. The suspected portion identification timer defines the above-described certain period of time.

Next, by performing the following process, only a failure at a highest level among power supply units and devices in which failures have been detected in the certain period of time is logged, and a portion in which the logged failure has occurred is identified as a suspected portion. That is, a suspected portion indicated by log information held by the log region 41 of the RAM 40 when the suspected portion identification timer has timed out is identified as a suspected portion (the unit 2 or 3 or the device 4) in which a failure that has occurred in the power supply system of the computer system 100 has occurred.

A plurality of failures might be transmitted in reception of one failure detection signal. Therefore, once a failure detection signal has been received, the processing unit 30 searches the entirety of the failure holding register 21 (for example, from the bit 21a to the bit 21h) for failures held by the failure holding register 21, and performs the process for identifying a suspected portion (steps S105 to S112). That is, once a failure detection signal has been received, the processing unit 30 determines whether or not the search of the failure holding register 21 has been completed up to a last bit (step S104). If the search of the failure holding register 21 has been completed up to the last bit (the YES route in step S104), the processing unit 30 returns to the processing in step S101, and waits for a failure detection signal from the holding unit 20. On the other hand, if the search of the failure holding register 21 has not been completed up to the last bit (the NO route in step S104), the processing unit 30 performs the process for identifying a suspected portion (steps S105 to S112).

When a failure has been found in the failure holding register 21, the processing unit 30 converts the failure into an alarm number provided for the failure, and searches the suspected portion identification table using the obtained alarm number as a key. In doing so, the processing unit 30 obtains registered information including an alarm number that matches the obtained alarm number, and determines the level of the registered information, that is, the level of the current failure (step S105). In the suspected portion identification table illustrated in FIG. 12, the alarm numbers 01, 02, 04, 14, 24, 05, 15, 25, N, N+1, and N+2 are provided for the failures (1) to (11), respectively.

Thereafter, the processing unit 30 begins a process for comparing the level of a detected failure (log information saved in the log region 41) and the level of the current failure (step S106).

First, the processing unit 30 determines whether or not there is the alarm number of a detected failure, that is, whether or not log information has been saved to the log region 41 (step S107). If there is no alarm number of a detected failure (NO in step S107), which means that the failure has been detected for the first time, the processing unit 30 generates new log information in the log region 41 of the RAM 40 (step S110). The log information includes the alarm number of the current failure and the suspected portion and the details of the failure indicated by the registered information read for the current failure from the suspected portion identification table. It is to be noted that the log information generated here may be referred to as “log information that is being generated” hereinafter. After generating the log information, the processing unit 30 returns to the processing in step S104.

If there is the alarm number of a detected failure (YES in step S107), the processing unit 30 refers to the alarm number of the detected failure in the log information that is being generated. The processing unit 30 then determines whether or not the alarm number that has been referred to belongs to a level higher than the level of the current failure (the level determined in step S105) in the suspected portion identification table (step S108).

If the alarm number of the detected failure belongs to a level higher than the level of the current failure in the suspected portion identification table (YES in step S108), the current failure belongs to a level lower than the level of the failure in the log information that is being generated. Therefore, the processing unit 30 ends the process for comparing the levels, and returns to the processing in step S104 without generating or updating the log information.

If the alarm number of the detected failure does not belong to a level higher than the level of the current failure in the suspected portion identification table (NO in step S108), the processing unit 30 refers to the alarm number of the detected failure in the log information that is being generated. The processing unit 30 then determines whether or not the alarm number that has been referred to belongs to a level lower than the level of the current failure (the level determined in step S105) in the suspected portion identification table (step S109).

If the alarm number of the detected failure belongs to a level lower than the level of the current failure in the suspected portion identification table (YES in step S109), the current failure belongs to a level higher than the level of the failure in the log information that is being generated. Therefore, the processing unit 30 updates the log information that is being generated in the log region 41 (step S111). That is, the processing unit 30 updates the alarm number of the detected failure in the log information that is being generated to the alarm number of the current failure. In addition, the processing unit 30 updates the suspected portion and the details of the failure in the log information that is being generated to the suspected portion and the details of the failure indicated by the registered information read for the current failure from the suspected portion identification table. After updating the log information, the processing unit 30 returns to the processing in step S104.

If the alarm number of the detected failure does not belong to a level lower than the level of the current failure in the suspected portion identification table (NO in step S109), it is considered that the current failure belongs to the same level as the failure in the log information that is being generated but belongs to a different power supply system. This state corresponds, for example, to a state (refer to FIG. 12) in which the failure in the log information that is being generated is the failure (4) and the current failure is the failure (7), which belongs to the same level as the failure (4). In such a case, the processing unit 30 generates log information different from the log information generated in step S110 (step S112). The log information includes the alarm number of the current failure and the suspected portion and the details of the failure indicated by the registered information read for the current failure from the suspected portion identification table. After generating the log information, the processing unit 30 returns to the processing in step S104.

When the suspected portion identification timer has timed out while the above-described process is being repeatedly executed, the alarm number at a highest level detected during the certain period of time and the suspected portion and the details of the failure corresponding to the alarm number are saved to the log region 41 as log information. That is, the log information that is being generated indicates the suspected portion (the unit 2 or 3 or the device 4) of the failure that has occurred in the power supply system of the computer system 100. Therefore, the processing unit 30 identifies the suspected portion indicated by the log information that is being generated as the suspected portion of the failure that has occurred in the power supply system of the computer system 100 (step S113).

A case in which a plurality of failures are detected and the specific operation of the processing unit 30 will be described hereinafter.

Here, a case will be described in which the input failure (1) has occurred in the AC-DC conversion unit 2 illustrated in FIG. 10 but the output voltage of the DC-DC conversion unit 3-1 illustrated in FIG. 10 decreases first due to variation in the characteristics of the units 2 and 3 and the processing unit 30 receives failures from the holding unit 20 in the following order [A] to [C].

[A] Internal failure (3) of DC-DC conversion unit 3-1 illustrated in FIG. 10

[B] Input failure (4) of device 4-1 illustrated in FIG. 10

[C] Input failure (1) of AC-DC conversion unit 2 illustrated in FIG.

[A] Processing for Input Failure (3) of DC-DC Conversion Unit 3-1

The processing unit 30 receives a failure detection signal (step S101) in accordance with setting of 1 to the bit 21c of the failure holding register 21, and then the processing unit 30 begins the process for identifying a suspected portion and activates the suspected portion identification timer (step S103).

The processing unit 30 searches the failure holding register 21 and finds the bit 21c, to which 1 has been set (the failure (3)). The processing unit 30 then obtains the alarm number “04” provided for the failure (3) and searches the suspected portion identification table using the alarm number “04” as a key. In doing so, the processing unit 30 obtains registered information including an alarm number that matches the alarm number “04”, and determines the level of the detected failure (3) (the third from the highest level) (step S105).

At this time, since there is no alarm number of a detected failure (NO in step S107), the processing unit 30 generates new log information in the log region 41 of the RAM 40 (step S110).

After searching the failure holding register 21 of the holding unit 20 up to the last bit (YES in S104), the processing unit 30 waits for reception of a failure detection signal since the failure holding register 21 does not hold another failure (step S101).

The content of the log information that is being generated at this time is as follows:

Suspected portion: DC-DC unit-1

Details of failure: Internal failure

Alarm number of detected failure: 04

[B] Processing for Input Failure (4) of Device 4-1

Next, the processing unit 30 receives a failure detection signal (step S101) in accordance with setting of 1 to the bit 21d of the failure holding register 21, and begins the process for identifying a suspected portion. At this time, since the suspected portion identification timer has been activated, the processing unit 30 skips the processing in step S102.

The processing unit 30 searches the failure holding register 21 and finds the bit 21d (the failure (4)), to which 1 has been set. The processing unit 30 then obtains the alarm number “14” provided for the failure (4) and searches the suspected portion identification table using the alarm number “14” as a key. In doing so, the processing unit 30 obtains registered information including an alarm number that matches the alarm number “14”, and determines the level of the detected failure (4) (the fourth from the highest level) (step S105).

Thereafter, the processing unit 30 searches the level of the failure detected this time (the fourth from the highest level) and higher levels for registered information including the alarm number that matches the alarm number “04” of the detected failure in the log information that is being generated. At this time, the processing unit 30 discovers the registered information including the alarm number that matches the alarm number “04” of the detected failure in the third level from the highest level. Therefore, the current failure belongs to a level lower than the level of the detected failure in the log information that is being generated (YES in step S108), and the processing unit 30 does not generate or update the log information.

After searching the failure holding register 21 of the holding unit 20 up to the last bit (YES in S104), the processing unit 30 waits for reception of a failure detection signal since the failure holding register 21 does not hold another failure (step S101).

The content of the log information that is being generated at this time is as follows:

Suspected portion: DC-DC unit-1

Details of failure: Internal failure

Alarm number of detected failure: 04

[C] Processing for Input Failure (1) of AC-DC Conversion Unit 2

Next, the processing unit 30 receives a failure detection signal (step S101) in accordance with setting of 1 to the bit 21a of the failure holding register 21, and begins the process for identifying a suspected portion. At this time, since the suspected portion identification timer has been activated, the processing unit 30 skips the processing in step S102.

The processing unit 30 searches the failure holding register 21 and finds the bit 21a (the failure (1)), to which 1 has been set. The processing unit 30 then obtains the alarm number “01” provided for the failure (1) and searches the suspected portion identification table using the alarm number “01” as a key. In doing so, the processing unit 30 obtains registered information including an alarm number that matches the alarm number “01”, and determines the level of the detected failure (1) (the highest level) (step S105).

Thereafter, the processing unit 30 searches the level of the failure (1) detected this time (the highest level) and lower levels for registered information including the alarm number that matches the alarm number “04” of the detected failure in the log information that is being generated. At this time, the processing unit 30 discovers the registered information including the alarm number that matches the alarm number “04” of the detected failure in the third level from the highest level. Therefore, the current failure belongs to a level higher than the level of the detected failure in the log information that is being generated (YES in step S109), and the processing unit 30 updates the log information that is being generated in the log region 41 (step S111). That is, the processing unit 30 updates the alarm number “04” of the detected failure in the log information that is being generated to the alarm number “01” of the current failure (1). In addition, the processing unit 30 updates the suspected portion and the details of the failure in the log information that is being generated to the suspected portion and the details of the failure indicated by the registered information read for the current failure (1) from the suspected portion identification table.

After searching the failure holding register 21 of the holding unit 20 up to the last bit (YES in S104), the processing unit 30 waits for reception of a failure detection signal since the failure holding register 21 does not hold another failure (step S101).

The content of the log information that is being generated at this time is as follows:

Suspected portion: AC-DC unit

Details of failure: Input failure

Alarm number of detected failure: 01

[D] Content of Resultant Log Information

When the suspected portion identification timer has timed out, the processing unit 30 completes the process for identifying a suspected portion. The processing unit 30 then identifies the suspected portion on the basis of the log information saved in the log region 41 of the RAM 40 and generates resultant log information (step S113).

The content of the resultant log information generated by the processing unit 30 is, for example, as follows:

Suspected portion: AC-DC unit (AC-DC conversion unit 2)

Details of failure: Input failure

Alarm number of detected failure: 01

[1-3] Power Supply State of Computer System When Failure of AC-DC Unit has been Detected

In the computer system 100 that is being used in these years, devices 4 to be mounted have been becoming diversified, and the number of devices 4 mounted has been increasing. Accordingly, the number of power supply units 2 and 3 mounted to supply power to a large number of devices 4 has also been increasing.

When the numbers of DC-DC conversion units 3 and devices 4 have increased and the AC-DC conversion unit 2 that supplies power to the DC-DC conversion units 3 also supplies power to the monitoring device 10, the following condition may occur.

If a failure occurs in the AC-DC conversion unit 2 at a high level, the DC-DC conversion units 3 and the devices 4 at low levels transmit a large number of failures to the monitoring device 10 in the certain period of time. When a large number of failures have been transmitted, the holding unit 20 simultaneously holds the failures at a plurality of levels, and the processing unit 30 repeatedly performs the process for identifying a suspected portion. Therefore, even if a failure occurs at the AC-DC conversion unit 2 at the highest level during the certain period of time, the processing unit 30 might not detect the failure of the AC-DC conversion unit 2 at the highest level until the processing unit 30 searches the entirety of the failure holding register 21. In this case, the supply of power to the monitoring device 10 might stop while the processing unit 30 is processing the failures of the DC-DC conversion units 3 and the devices 4, and accordingly it becomes difficult for the processing unit 30 to identify the AC-DC conversion unit 2 as a suspected portion.

On the other hand, when a unit different from the AC-DC conversion unit 2 that supplies power to the DC-DC conversion units 3 supplies power to the monitoring device 10, the following condition may occur.

If a failure occurs in the AC-DC conversion unit 2 that supplies power to the DC-DC conversion units 3 while the other unit is normally supplying power to the monitoring device 10, the DC-DC conversion units 3 and the devices 4 at levels lower than the level of the AC-DC conversion unit 2 transmit a large number of failures to the monitoring device 10. When a large number of failures have been transmitted while the processing unit 30 is performing processing other than the monitoring of the units 2 and 3 and the devices 4 for failures, a load on the processing unit 30 caused by the process for identifying a suspected portion increases, and therefore it might become difficult for the processing unit 30 to execute the processing other than the monitoring, thereby stopping the operation of the computer system 100. For example, when the processing unit 30 regularly communicates with a higher device in the computer system 100, a process for communicating with the higher device might not be executed if the load on the processing unit 30 caused by the process for identifying a suspected portion increases, and the higher device determines that a failure has occurred in the monitoring device 10, and stops the operation of the computer system 100.

A similar condition occurs when the AC-DC conversion unit 2 that supplies power to the DC-DC conversion units 3 also supplies power to the monitoring device 10. For example, if power is normally supplied to the monitoring device 10 but the input voltage of the DC-DC conversion units 3 and the devices 4 decreases due to an instantaneous power failure in the AC-DC conversion unit 2 and a resultant increase in a load on the devices 4 side, the same condition as above may occur.

In addition, when, in the process for identifying a suspected portion performed by the processing unit 30, the numbers of AC-DC conversion units 2, DC-DC conversion units 3, and devices 4 have increased, the number of unique alarm numbers provided for the AC-DC conversion units 2, the DC-DC conversion units 3, and the devices 4 and the number of hierarchical tables also increase. Accordingly, the processing unit 30 takes time to perform a process for determining the level of a detected failure, and the load on the processing unit 30 caused by the process for determining the level of a failure, that is, the process for identifying a suspected portion, becomes large.

### [2] First Embodiment

[2-1] Configuration According to First Embodiment

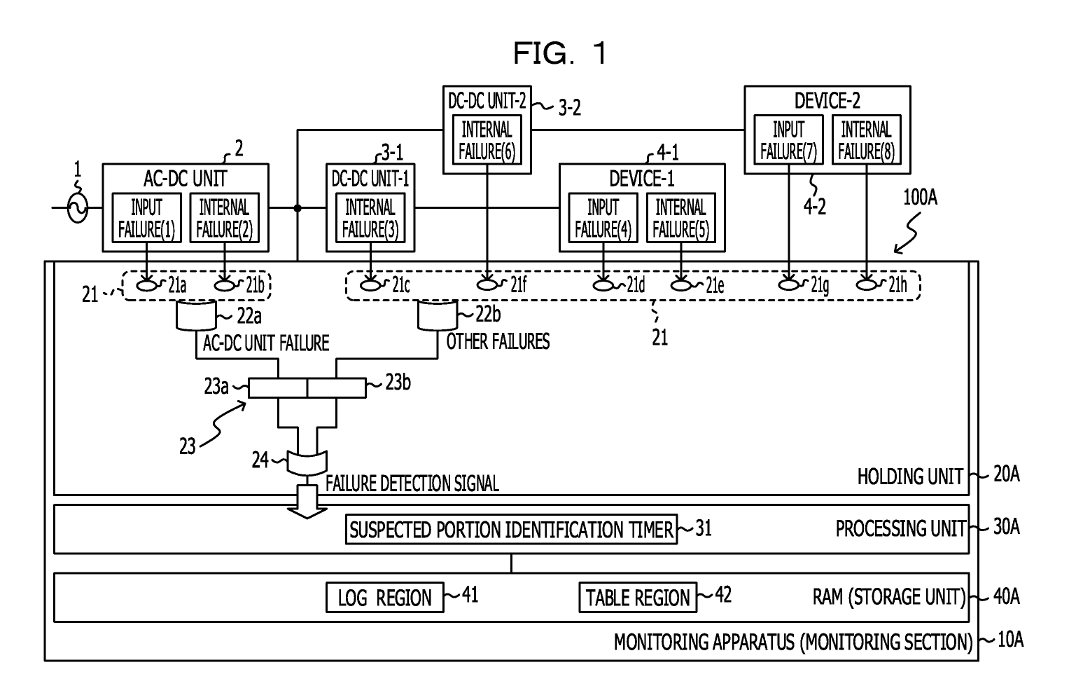

The configuration of an information processing apparatus 100A including a monitoring device 10A according to a first embodiment will be described with reference to FIG. 1. FIG. 1 is a block diagram illustrating the configuration of the information processing apparatus 100A including the monitoring device 10A according to the first embodiment. Because the same reference numerals as those mentioned above denote the same or substantially the same components, detailed description of such components is omitted.

As with the monitoring device 10 illustrated in FIG. 10, the monitoring device (monitoring section) 10A monitors devices 4 and a power supply system for the devices 4 for failures in the information processing apparatus (computer system) 100A.

In the first embodiment, as with the example illustrated in FIG. 10, the power supply system for the devices 4 is hierarchized, and an AC-DC conversion unit 2 that converts alternating current from an alternating-current power supply 1 into direct current is mounted as a power supply unit (first power supply unit) at a high level. In addition, DC-DC conversion units 3-1 and 3-2 that convert the direct current from the AC-DC conversion unit 2 and that supply resultant direct current to devices 4-1 and 4-2, respectively, are mounted as power supply units (second power supply units) at a low level. Supply of power to the monitoring device 10A is performed by the AC-DC conversion unit 2 that supplies power to the DC-DC conversion units 3.

The monitoring device 10A includes a holding unit 20A, a processing unit (monitoring processing unit) 30A, and a RAM (storage unit) 40A.

As with the above-described holding unit 20, the holding unit 20A includes a failure holding register 21 that receives and holds failure signals transmitted from the units 2 and 3 and the devices 4. The holding unit 20A is an example of the holding circuit. The failure holding register 21 is an example of the storage.

Here, the AC-DC conversion unit 2, the DC-DC conversion units 3, and the devices 4 have a function of transmitting failure signals to the monitoring device 10 upon detecting failures that have occurred therein, respectively.

In addition, in the first embodiment, too, the failures (1) to (8) illustrated in FIG. 10 are used, and if the failures (1) to (8) occur, 1 is set to bits 21a to 21h, respectively, of the failure holding register 21 of the holding unit 20A.

The holding unit 20A includes OR circuits 22a, 22b, and 24 and a factor holding register 23. The factor holding register 23 is an example of the storage.

The OR circuit 22a sets a logical sum of the values of the two bits 21a and 21b that hold the failures (1) and (2) (first failures), respectively, of the AC-DC conversion unit 2 to a bit 23a of the factor holding register 23 as “AC-DC_unit failure” (a first failure). That is, if at least either the failure (1) or (2) of the AC-DC conversion unit 2 occurs, “AC-DC_unit failure”, which is the output of the OR circuit 22a, switches to 1, and the value of the bit 23a of the factor holding register 23 is set to 1.

The OR circuit 22b sets a logical sum of the values of the bits 21c to 21h, which hold the failures (3) to (8) (second failures), respectively, of the DC-DC conversion units 3 and the devices 4 to a bit 23b of the factor holding register 23 as “other failures” (a second failure). That is, if at least one of the failures (3) to (8) of the DC-DC conversion units 3 and the devices 4 occurs, “other failures”, which is the output of the OR circuit 22b, switches to 1, and accordingly the value of the bit 23b of the factor holding register 23 is set to 1. In the following description, the failures (3) to (8) of the DC-DC conversion units 3 and the devices 4 are generically called “other failures”.

The OR circuit 24 regularly, or in accordance with an interrupt signal, generates a logical sum of the values of the two bits 23a and 23b of the factor holding register 23 as a failure detection signal and transmits the failure detection signal to the processing unit 30A, in order to notify the processing unit 30A of occurrence of a failure in the power supply system. That is, if at least one of the bits 21a to 21h is 1, the holding unit 20A continues to transmit a failure detection signal to the processing unit 30A until the processing unit 30A completes a process for identifying a suspected portion and resets all failures held by the failure holding register 21 (resets all the values of the bits 21a to 21h to 0).

The processing unit 30A identifies, in accordance with steps S11 to S19, which will be described later, the unit 2 or 3 or the device 4 in which a failure has occurred on the basis of a failure held by the holding unit 20A and a suspected portion identification table (the hierarchical tables T1 to TN; refer to FIG. 12) held by a table region 42 of the RAM 40A.

The processing unit 30A includes a suspected portion identification timer 31 that begins to measure a certain period of time upon receiving a failure detection signal, that is, a signal indicating that the holding unit 20A has held “AC-DC_unit failure” or “other failures”, from the holding unit 20A. As described above, the certain period of time is time assumed to be taken until all of one or more failures relating to a certain failure are transmitted after the certain failure is transmitted (after a failure detection signal is received). In other words, the certain period of time is time assumed to be taken until the holding unit 20A holds all of one or more failures relating to a certain failure after the holding unit 20A holds the certain failure.

Upon receiving a failure detection signal from the holding unit 20A, the processing unit 30A activates the timer 31. If the holding unit 20A holds “AC-DC_unit failure”, the processing unit 30A gives priority to “AC-DC_unit failure” over “other failures”, and identifies a suspected portion (first suspected portion) in which “AC-DC_unit failure” has occurred until the certain period of time has elapsed since the timer 31 was activated. On the other hand, if the holding unit 20A does not hold “AC-DC_unit failure” and holds “other failures”, the processing unit 30A identifies a suspected portion (second suspected portion) in which “other failures” has occurred.

At this time, the processing unit 30A determines whether or not “AC-DC_unit failure” (first failure) is held by referring to the value of the bit 23a of the factor holding register 23 and whether or not “other failures” (second failure) is held by referring to the value of the bit 23b of the factor holding register 23.

In addition, as with the above-described processing unit 30, the processing unit 30A provides individual failures held by the failure holding register 21 (the bits 21a to 21h) of the holding unit 20A with unique alarm numbers. Upon receiving a failure detection signal from the holding unit 20A, the processing unit 30A replaces a failure held by the failure holding register 21 with an alarm number, and executes the process for identifying a suspected portion.

[2-2] Operation According to First Embodiment

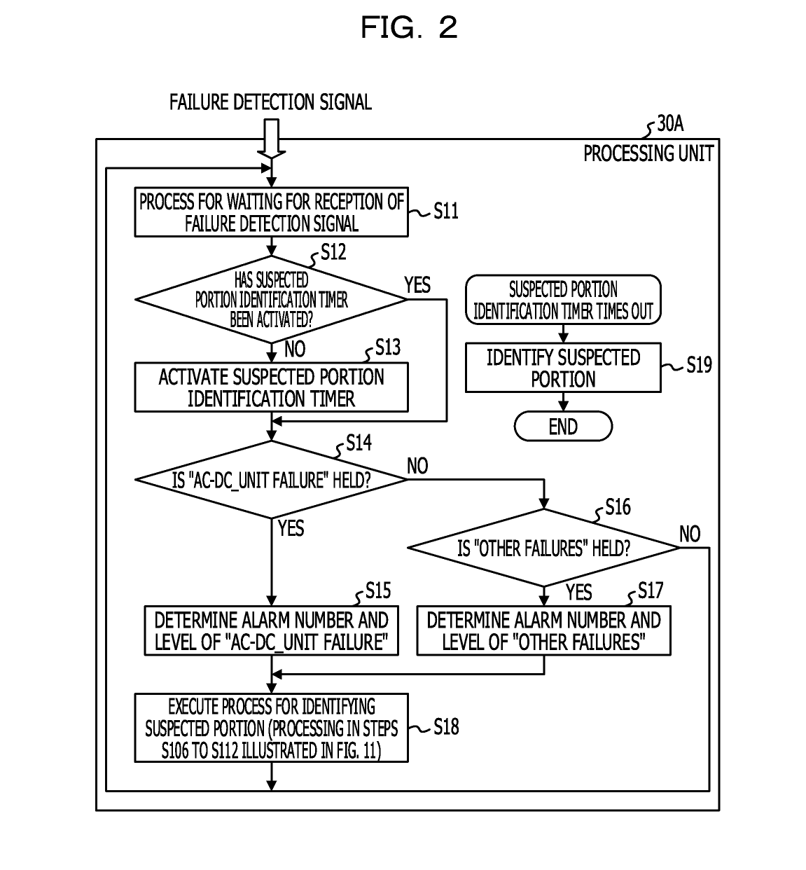

Next, the process for identifying a suspected portion (monitoring processing procedure) executed by the processing unit 30A after the processing unit 30A receives a failure detection signal from the holding unit 20A will be described in detail with reference to a flowchart (steps S11 to S19) of FIG. 2.

In the initial state of the monitoring device 10A, 0 is set to the bits 21a to 21h of the failure holding register 21 and the bits 23a and 23b of the factor holding register 23, and the timer 31 that measures a period of time (the above-described period of time) in which the suspected portion is identified has not been activated. All log information in a log region 41 of the RAM 40A has been deleted.

The processing unit 30A continuously waits for a signal transmitted from the holding unit 20A (step S11).

Since the suspected portion identification timer 31 has not been activated (NO in step S12) when the processing unit 30A has received a failure detection signal from the holding unit 20A for the first time, the processing unit 30A activates the timer 31 (step S13), and proceeds to processing in step S14. If the timer 31 has already been activated (YES in step S12), the processing unit 30A proceeds to the processing in step S14 without performing the processing in step S13.

The processing unit 30A refers to the bit 23a of the factor holding register 23 of the holding unit 20A, and if 1 is set to the bit 23a, the processing unit 30A determines that “AC-DC_unit failure” is held by the holding unit 20A (YES in step S14). In this case, the processing unit 30A searches the bits 21a and 21b, which relate to “AC-DC_unit failure”, of the failure holding register 21 for a failure. The processing unit 30A then converts a found failure into an alarm number provided for the failure, and searches the suspected portion identification table (refer to FIG. 12) using the alarm number as a key. In doing so, the processing unit 30A obtains registered information including an alarm number that matches the obtained alarm number, and determines the level of the registered information, that is, the level of “AC-DC_unit failure” that has been found this time (step S15). Thereafter, the processing unit 30A performs the same process for identifying a suspected portion as that represented by steps S106 to S112 illustrated in FIG. 11 for “AC-DC_unit failure” that has been found this time (step S18), and returns to the waiting process in step S11.

If 0 is set to the bit 23a, the processing unit 30A determines that “AC-DC_unit failure” is not held by the holding unit 20A (NO in step S14), and refers to the bit 23b of the factor holding register 23 of the holding unit 20A. If 0 is set to the bit 23b, the processing unit 30A determines that the holding unit 20A does not hold any failure (NO in step S16), and returns to the waiting process in step S11 without performing the process for identifying a suspected portion.

On the other hand, if 1 is set to the bit 23b, the processing unit 30A determines that the holding unit 20A holds “other failures” (YES in step S16). In this case, the processing unit 30A searches the bits 21c to 21h, which relate to “other failures”, of the failure holding register 21 for a failure. The processing unit 30A then converts a found failure into an alarm number provided for the failure, and searches the suspected portion identification table (refer to FIG. 12) using the obtained alarm number as a key. In doing so, the processing unit 30A obtains registered information including an alarm number that matches the obtained alarm number, and determines the level of the registered information, that is, the level of “other failures” that has been found this time (step S17). Thereafter, the processing unit 30A performs the same process for identifying a suspected portion as that represented by step S106 to S112 illustrated in FIG. 11 for “other failures” that has been found this time (step S18), and returns to the waiting process in step S11.

When the certain period of time has elapsed and the suspected portion identification timer 31 has timed out while the above-described process (step S11 to S18) is being repeatedly executed, an alarm number at a highest level detected during the certain period of time and a suspected portion and details of the failure corresponding to the alarm number are saved to the log region 41 as log information. That is, the log information that is being generated indicates the suspected portion (the unit 2 or 3 or the device 4) of the failure that has occurred in the power supply system of the computer system 100A. Therefore, the processing unit 30A identifies the suspected portion indicated by the log information that is being generated as the suspected portion of the failure that has occurred in the power supply system of the computer system 100A (step S19).

According to the monitoring device 10A (processing unit 30A) according to the first embodiment, because of the above-described process (steps S11 to S18), “AC-DC_unit failure” takes priority over “other failures” in processing for the certain period of time since a failure detection signal was received from the holding unit 20A.

In addition, in the monitoring device 10 illustrated in FIG. 10, the processing unit 30 waits for reception of a failure detection signal after searching all the bits 21a to 21h of the failure holding register 21 (refer to the YES route in step S104 to step S101). In contrast, the processing unit 30A according to the first embodiment waits for a failure detection signal after performing the process for identifying a suspected portion for one failure (refer to the route from step S18 to step S11), and “AC-DC_unit failure” takes priority over “other failures” in processing.

Therefore, according to the monitoring device 10A according to the first embodiment, even if “other failures”, that is, failures of the DC-DC conversion units 3 and the devices 4, occur a large number of times, it is possible to identify the AC-DC conversion unit 2 as the suspected portion before the AC-DC conversion unit 2 stops supplying power to the monitoring device 10A. That is, according to the monitoring device 10A according to the first embodiment, even if the numbers of DC-DC conversion units 3 and devices 4 mounted increase, a suspected portion of the power supply system in which a failure has occurred may be easily identified.

### [3] Second Embodiment

[3-1] Configuration According to Second Embodiment

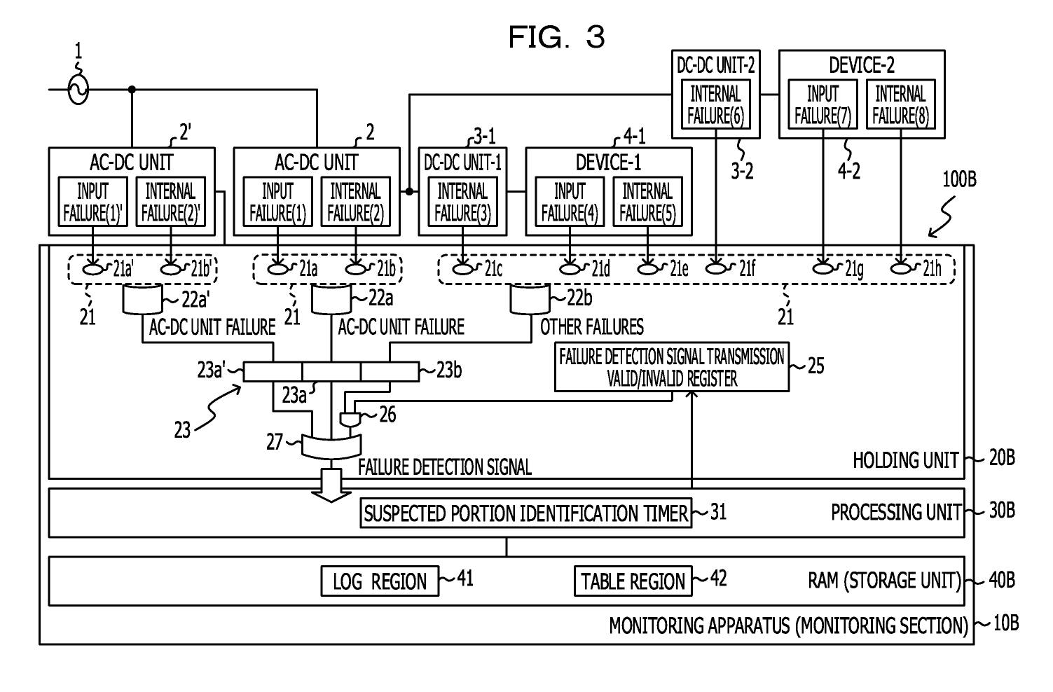

The configuration of an information processing apparatus 100b including a monitoring device 10B according to a second embodiment will be described with reference to FIG. 3. FIG. 3 is a block diagram illustrating the configuration of the information processing apparatus 100B including the monitoring device 10B according to the second embodiment. Because the same reference numerals as those mentioned above denote the same or substantially the same components, detailed description of such components is omitted.

As with the above-described monitoring devices 10 and 10A, the monitoring device (monitoring section) 10B according to the second embodiment monitors devices 4 and a power supply system for the devices 4 for failures in the information processing apparatus (computer system) 100B.

In the second embodiment, too, the power supply system for the devices 4 is hierarchized, and an AC-DC conversion unit 2 that converts alternating current from an alternating-current power supply 1 into direct current is mounted as a power supply unit (first power supply unit) at a high level. In addition, DC-DC conversion units 3-1 and 3-2 that convert the direct current from the AC-DC conversion unit 2 and that supply resultant direct current to devices 4-1 and 4-2, respectively, are mounted as power supply units (second power supply units) at a low level. In the second embodiment, supply of power to the monitoring device 10B is performed by an AC-DC conversion unit 2′ that is different from the AC-DC conversion unit 2, which supplies power to the DC-DC conversion units 3.

The monitoring device 10B includes a holding unit 20B, a processing unit (monitoring processing unit) 30B, and a RAM (storage unit) 40B.

The holding unit 20B includes a failure holding register 21 that receives and holds failure signals transmitted from the units 2, 2′ and 3 and the devices 4. The holding unit 20B is an example of the holding circuit. The failure holding register 21 is an example of the storage. However, in the failure holding register 21 of the holding unit 20B, bits 21a′ and 21b′ corresponding to an input failure (1)′ and an internal failure (2)′, respectively, of the AC-DC conversion unit 2′ are added to the bits 21a to 21h corresponding to the failures (1) to (8), respectively. If the failures (1)′ and (2)′ occur, 1 is set to the bits 21a′ and 21b′, respectively, of the failure holding register 21 of the holding unit 20B.

In addition, the holding unit 20B includes OR circuits 22a, 22a′, 22b, and 27, a factor holding register 23, a failure detection signal transmission valid/invalid register 25, and an AND circuit 26. The factor holding register 23 and the failure detection signal transmission valid/invalid register 25 are examples of the storage.

The OR circuits 22a and 22b are the same as those described above with reference to FIG. 1, and therefore description thereof is omitted.

The OR circuit 22a′ sets a logical sum of the values of the two bits 21a′ and 21b′, which hold the failures (1)′ and (2)′, respectively, of the AC-DC conversion unit 2′, to a bit 23a′ of the factor holding register 23 as “AC-DC_unit failure” (a first failure). That is, if at least either the failure (1)′ or (2)′ of the AC-DC conversion unit 2′ occurs, “AC-DC_unit failure”, which is the output of the OR circuit 22a′, switches to 1, and accordingly the value of the bit 23a′ of the factor holding register 23 is set to 1.

The processing unit 30B sets a value of 1 or 0 to the failure detection signal transmission valid/invalid register 25. When a failure detection signal regarding “other failures” (a second failure) is to be validated, that is, when a transmission operation for transmitting a signal indicating that the holding unit 20B has held “other failures” from the holding unit 20B to the processing unit 30B is to be permitted, the processing unit 30B set 1 to the failure detection signal transmission valid/invalid register 25. On the other hand, when a failure detection signal regarding “other failures” is to be invalidated, that is, when the transmission operation for transmitting a signal indicating that the holding unit 20B has held “other failures” from the holding unit 20B to the processing unit 30B is to be suppressed, the processing unit 30B sets 0 to the failure detection signal transmission valid/invalid register 25. In the initial state, 1 is set to the failure detection signal transmission valid/invalid register 25.

The AND circuit 26 outputs a logical multiplication of the value of the bit 23b of the factor holding register 23 and the value of the failure detection signal transmission valid/invalid register 25.

The failure detection signal transmission valid/invalid register 25 and the AND circuit 26 function as a switching unit that switches the permitted/suppressed state of the transmission operation for transmitting a signal indicating that the holding unit 20B has held “other failures” from the holding unit 20B to the processing unit 30B. The switching unit is an example of a switching circuit.

The OR circuit 27 regularly, or in accordance with an interrupt signal, generates a logical sum of the values of two bits 23a and 23a′ of the factor holding register 23 and the value from the AND circuit 26 as a failure detection signal and transmits the failure detection signal to the processing unit 30B. That is, if 0 is set to the failure detection signal transmission valid/invalid register 25, the OR circuit 27 transmits a failure detection signal regarding “AC-DC_unit failure” to the processing unit 30B, but does not transmit a failure detection signal regarding “other failures” to the processing unit 30B. On the other hand, if 1 is set to the failure detection signal transmission valid/invalid register 25, the OR circuit 27 transmits both a failure detection signal regarding “AC-DC_unit failure” and a failure detection signal regarding “other failures” to the processing unit 30B.

The processing unit 30B identifies, in accordance with steps S21 to S32, which will be described later, the unit 2 or 3 or the device 4 in which a failure has occurred on the basis of a failure held by the holding unit 20B and a suspected portion identification table (refer to FIG. 12) held by a table region 42 of the RAM 40B. The suspected portion identification table according to the second embodiment includes not only an array table (hierarchical tables T1 to TN) for registered information regarding the above-described failures (1) to (11) but also an array table (omitted in the figure) representing hierarchized registered information regarding the failures (1)′ and (2)′ of the AC-DC conversion unit 2′.

The processing unit 30B includes a suspected portion identification timer 31 that is the same as that according to the first embodiment.

Upon receiving a failure detection signal, that is, a signal indicating that the holding unit 20B has held “AC-DC_unit failure” or “other failures”, from the holding unit 20B, the processing unit 30B activates the timer 31, and updates the value of the failure detection signal transmission valid/invalid register 25 from 1 to 0. The transmission operation for transmitting a signal indicating that the holding unit 20B has held “other failures” from the holding unit 20B to the processing unit 30B is suppressed while the value of the failure detection signal transmission valid/invalid register 25 is 0.

The processing unit 30B searches the bits 21a, 21b, 21a′, and 21b′, which relate to “AC-DC_unit failure”, of the failure holding register 21 and performs a process for identifying a suspected portion (first suspected portion) in which “AC-DC_unit failure” has occurred until the certain period of time has elapsed since the timer 31 was activated. In the process, the processing unit 30B uses a portion (tables at highest two levels illustrated in the left half of FIG. 12) of the suspected portion identification table for identifying the suspected portion of “AC-DC_unit failure”.

Since the transmission operation for transmitting a signal indicating that the holding unit 20B has held “other failures” from the holding unit 20B to the processing unit 30B is suppressed during the period, the processing unit 30B does not perform a process for identifying a suspected portion (second suspected portion) in which “other failures” has occurred. That is, during the period, the processing unit 30B gives priority to “AC-DC_unit failure” over “other failures”, and identifies a suspected portion in which “AC-DC_unit failure” has occurred.

On the other hand, if the suspected portion of “AC-DC_unit failure” has not been identified when the timer 31 has measured the certain period of time, the processing unit 30B performs the process for identifying a suspected portion in which “other failures” has occurred. In the process, the processing unit 30B uses a portion (tables at lowest three levels illustrated in the right half of FIG. 12) of the suspected portion identification table for identifying the suspected portion of “other failures”. That is, the processing unit 30B searches for “other failures” held by the holding unit 20B (the bits 21c to 21h) to identify a suspected portion in which found “other failures” has occurred, and then updates the value of the failure detection signal transmission valid/invalid register 25 from 0 to 1. In doing so, the transmission operation for transmitting a signal indicating that the holding unit 20B has held “other failures” from the holding unit 20B to the processing unit 30B is permitted. If the suspected portion of “AC-DC_unit failure” has been identified when the timer 31 has measured the certain period of time, the processing unit 30B updates the value of the failure detection signal transmission valid/invalid register 25 from 0 to 1 without performing the process for identifying a suspected portion in which “other failures” has occurred.

At this time, the processing unit 30B determines whether or not “AC-DC_unit failure” (a first failure) is held by referring to the values of the bits 23a and 23a′ of the factor holding register 23 and whether or not “other failures” (a second failure) is held by referring to the value of the bit 23b of the factor holding register 23.

In addition, as with the above-described processing units 30 and 30A, the processing unit 30B provides individual failures held by the failure holding register 21 (the bits 21a to 21h, 21a′, and 21b′) of the holding unit 20B with unique alarm numbers. Upon receiving a failure detection signal from the holding unit 20B, the processing unit 30B replaces a failure held by the failure holding register 21 with an alarm number, and executes the process for identifying a suspected portion.

[3-2] Operation According To Second Embodiment

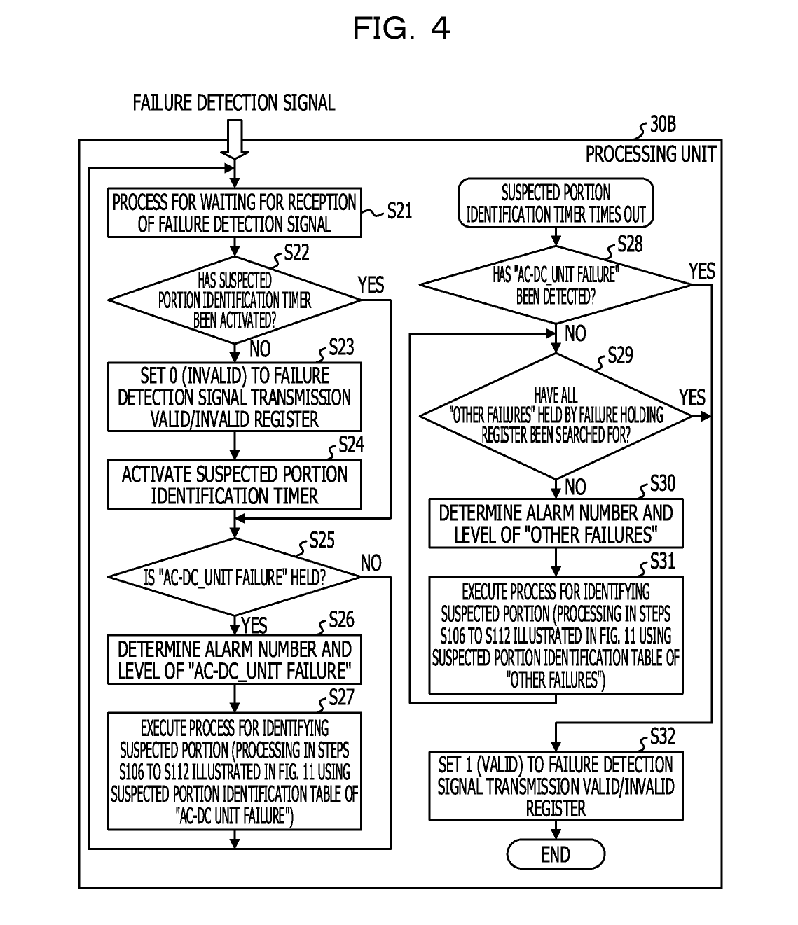

Next, the process for identifying a suspected portion (monitoring processing procedure) executed by the processing unit 30B after the processing unit 30B receives a failure detection signal from the holding unit 20B will be described in detail with reference to a flowchart (steps S21 to S32) of FIG. 4.

In the initial state of the monitoring device 10B, 0 is set to the bits 21a to 21h, 21a′, and 21b′ of the failure holding register 21 and the bits 23a, 23a′, and 23b of the factor holding register 23, and 1 is set to the failure detection signal transmission valid/invalid register 25. The timer 31 that measures a period of time (the above-described period of time) in which the suspected portion is identified has not been activated. All log information in a log region 41 of the RAM 40B has been deleted.

The processing unit 30B continuously waits for a signal transmitted from the holding unit 20B (step S21).

If the suspected portion identification timer 31 has not been activated (NO in step S22) when the processing unit 30B has received a failure detection signal from the holding unit 20B for the first time, the processing unit 30B performs the following process. That is, the processing unit 30B updates the value of the failure detection signal transmission valid/invalid register 25 from 1 to 0, and suppresses the transmission operation for transmitting a failure detection signal regarding “other failures” from the holding unit 20B to the processing unit 30B (step S23). In addition, the processing unit 30B activates the timer 31 (step S24). Thereafter, the processing unit 30B proceeds to processing in step S25. If the timer 31 has already been activated (YES in step S22), the processing unit 30B proceeds to the processing in step S25 without performing the processing in steps S23 and S24. The order in which steps S23 and S24 are executed may be reversed.

The processing unit 30B refers to the bits 23a and 23a′ of the factor holding register 23 of the holding unit 20B, and if 1 is set to at least either the bit 23a or 23a′, the processing unit 30B determines that “AC-DC_unit failure” is held by the holding unit 20B (YES in step S25). In this case, the processing unit 30B searches the bits 21a, 21b, 21a′ and 21b′, which relate to “AC-DC_unit failure”, of the failure holding register 21 for a failure. The processing unit 30B then converts a found failure into an alarm number provided for the failure, and searches the suspected portion identification table (refer to FIG. 12) using the alarm number as a key. In doing so, the processing unit 30B obtains registered information including an alarm number that matches the obtained alarm number, and determines the level of the registered information, that is, the level of “AC-DC_unit failure” that has been found this time (step S26). Thereafter, the processing unit 30B performs the same process for identifying a suspected portion as that represented by steps S106 to S112 illustrated in FIG. 11 for “AC-DC_unit failure” that has been found this time (step S27), and returns to the waiting process in step S21. In the process for identifying a suspected portion, as described above, the processing unit 30B uses a portion (tables at highest two levels illustrated in the left half of FIG. 12) of the suspected portion identification table for identifying the suspected portion of “AC-DC_unit failure”.

If 0 is set to both the bits 23a and 23a′, the processing unit 30B determines that “AC-DC_unit failure” is not held by the holding unit 20B (NO in step S25), and returns to the waiting process in step S21 without performing the process for identifying a suspected portion.

When the certain period of time has elapsed and the certain period of time has timed out while the above-described process (step S21 to S27) is being repeatedly executed, the processing unit 30B proceeds to processing in step S28.

In step S28, the processing unit 30B refers to the log region 41 of the RAM 40B to determine whether or not “AC-DC_unit failure” has been detected, that is, whether or not the alarm number of a detected failure has been registered.

If the alarm number of a detected failure has been registered (YES in step S28), the suspected portion of “AC-DC_unit failure” has already been identified, and log information regarding “AC-DC_unit failure” that has been detected in the certain period of time has been saved to the log region 41. Therefore, the processing unit 30B updates the value of the failure detection signal transmission valid/invalid register 25 from 0 to 1 (step S32) without performing the process for identifying a suspected portion for “other failures”. In doing so, the processing unit 30B permits the transmission operation for transmitting a failure detection signal regarding “other failures” from the holding unit 20B to the processing unit 30B, and ends the process.

On the other hand, if the alarm number of a detected failure has not been registered (NO in step S28), the processing unit 30B performs the process for identifying a suspected portion in which “other failures” has occurred. In this case, the processing unit 30B searches for each of “other failures” held by the failure holding register 21 (NO in step S29), and converts a detected failure into an alarm number provided for the failure. The processing unit 30B then searches the suspected portion identification table (refer to FIG. 12) using the obtained alarm number as a key. In doing so, the processing unit 30B obtains registered information including an alarm number that matches the obtained alarm number, and determines the level of the registered information, that is, the level of “other failures” that has been found this time (step S30). Thereafter, the processing unit 30B performs the same process for identifying a suspected portion as that represented by steps S106 to S112 illustrated in FIG. 11 for “other failures” that has been found this time, and returns to the processing in step S29. In the process for identifying a suspected portion, as described above, the processing unit 30B uses a portion (tables at the lowest three levels illustrated in the right half of FIG. 12) of the suspected portion identification table for identifying the suspected portion of “other failures”.

The processing unit 30B repeatedly executes the processing in steps S30 and S31 until all of “other failures” held by the failure holding register 21 have been found. When all of “other failures” held by the failure holding register 21 are found (YES in step S29), the processing unit 30B updates the value of the failure detection signal transmission valid/invalid register 25 from 0 to 1 (step S32). In doing so, the processing unit 30B permits the transmission operation for transmitting a failure detection signal regarding “other failures” from the holding unit 20B to the processing unit 30B, and ends the process.

“AC-DC_unit failure” is a suspected portion at a highest level. Therefore, when “AC-DC_unit failure” has been detected, the suspected portions of “other failures” that have been detected before the timer 31 times out are not to be identified.

On the other hand, if “AC-DC_unit failure” has not been detected when the timer 31 has timed out, a suspected portion at the highest level is to be identified from among “other failures” that have been detected.

When “AC-DC_unit failure” has not been found but “other failures” has been detected in the information processing apparatus 100B, it means that failures of the devices 4 have been detected in accordance with occurrence of a failure of the DC-DC conversion units 3 or that a failure has independently occurred in the DC-DC conversion units 3 or the devices 4. In this case, a large number of “other failures” do not occur.

Therefore, as described above, the monitoring device 10B (processing unit 30B) according to the second embodiment is configured in such a way as to invalidate transmission of a failure detection signal regarding “other failures” held by the failure holding register 21. In addition, the process for identifying a suspected portion is divided into a process for identifying a suspected portion for “AC-DC_unit failure” and a process for identifying a suspected portion for “other failures”, and the process for identifying a suspected portion for “AC-DC_unit failure” is executed first, and then the process for identifying a suspected portion for “other failures” is executed after the timer 31 times out. At this time, the suspected portion identification table (refer to FIG. 12) is divided into a portion for “AC-DC_unit failure” and a portion for “other failures” and used.

By executing the above-described process (steps S21 to S32) using such a configuration, even if a large number of “other failures” occur, only the process for identifying a suspected portion for “AC-DC_unit failure” is executed until the timer 31 times out. In doing so, the suspected portion of “AC-DC_unit failure” that might result in a large number of “other failures” is identified first, and if “AC-DC_unit failure” has already been identified when the timer 31 has timed out, the process for identifying a suspected portion for “other failures” is not executed. The process for identifying a suspected portion for “other failures” is executed if “AC-DC_unit failure” has not been detected.

Therefore, a load on the processing unit 30B caused by the process for identifying a suspected portion for “other failures” becomes small in a period in which a large number of “other failures” occur. Therefore, a situation may be avoided in which it becomes difficult for the processing unit 30B to execute processing other than the monitoring for failures and the operation of the information processing apparatus 100B stops while the processing unit 30B is performing the processing other than the monitoring for failures. As a result, the processing unit 30B may steadily continue and assure the operation thereof. As with the first embodiment, the monitoring device 10B according to the second embodiment may easily identify a suspected portion of the power supply system in which a failure has occurred even if the numbers of DC-DC conversion units 3 and devices 4 mounted increase.

### [4] Third Embodiment

[4-1] Configuration According to Third Embodiment

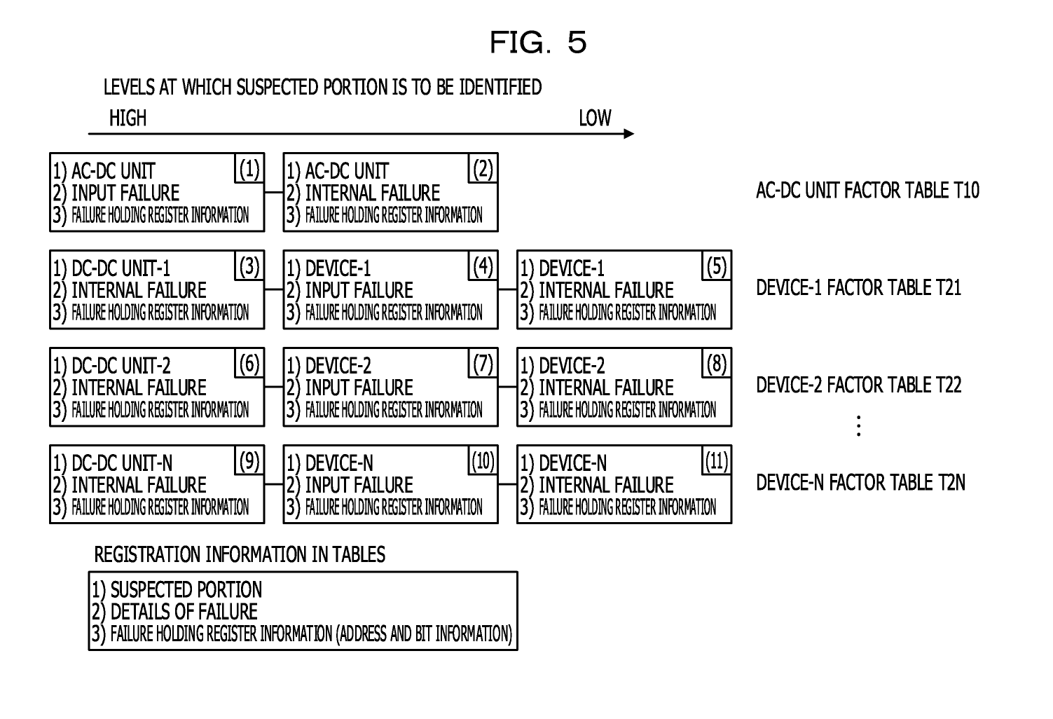

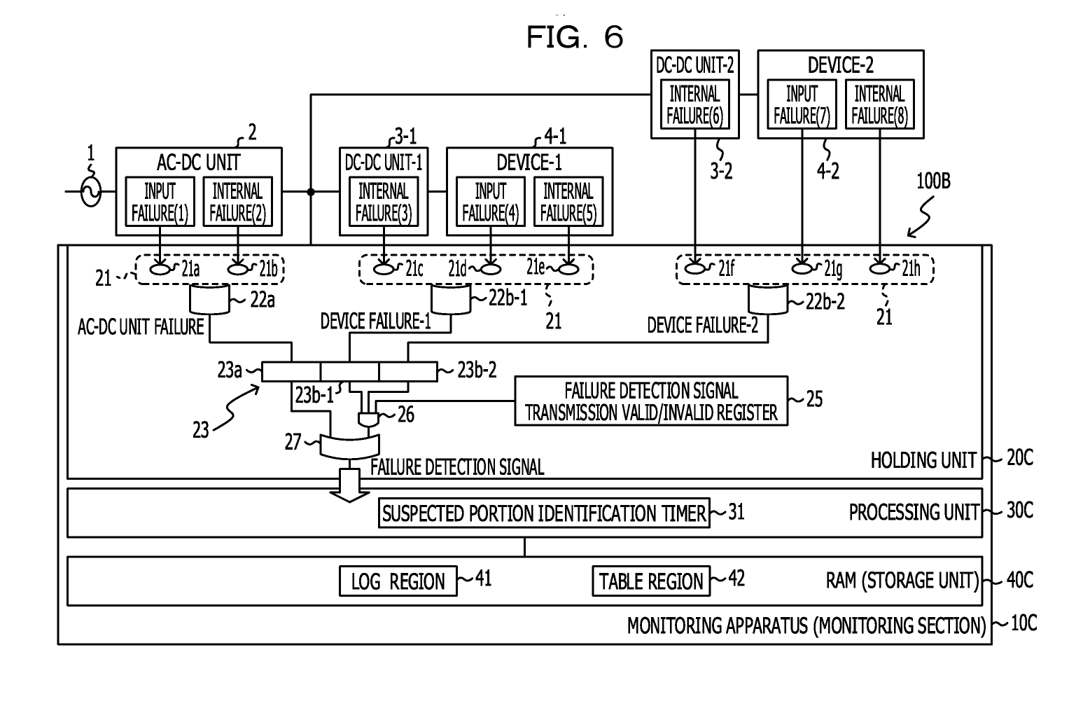

The configuration of an information processing apparatus 100C including a monitoring device 10C according to a third embodiment will be described with reference to FIGS. 5 and 6. FIG. 5 is a diagram illustrating an example of a suspected portion identification table used by the monitoring device 10C according to the third embodiment, and FIG. 6 is a block diagram illustrating the configuration of the information processing apparatus 100C including the monitoring device 10C according to the third embodiment. Because the same reference numerals as those mentioned above denote the same or substantially the same components, detailed description of such components is omitted.

First, the suspected portion identification table used by the monitoring device 10C according to the third embodiment will be described with reference to FIG. 5. In the monitoring device 10C according to the third embodiment, the suspected portion identification table illustrated in FIG. 5 is used instead of the suspected portion identification table (refer to FIG. 12) used in the first and second embodiments. The suspected portion identification table illustrated in FIG. 5 is saved in a table region 42 of a RAM 40C, which will be described later, and includes a plurality of factor tables T10 and T21 to T2N generated by a processing unit 30C, which will be described later.

The factor tables T10 and T21 to T2N are generated for individual factors held by a factor holding register 23 (refer to FIG. 6). That is, the factor tables T10, T21, and T22 correspond to bits 23a, 23b-1, and 23b-2, respectively, of the factor holding register 23. In FIG. 6, bits of the factor holding register 23 corresponding to the factor tables T23 to T2N are omitted.

The factor table (first table) T10 hierarchically defines information regarding the failures (1) and (2) of an AC-DC conversion unit 2, that is, failures relating to “AC-DC_unit failure” (a first failure). In the factor table T10, registered information regarding the hierarchically successive failures (1) and (2) is arranged in a hierarchical order.

The factor tables (second tables) T21 to T2N hierarchically define information regarding the failures (3) to (11) of DC-DC conversion units 3 and devices 4, that is, failures relating to “other failures”. In the factor table T21 for a device 4-1, registered information regarding the hierarchically successive failure (3) to (5) is hierarchically arranged. In the factor table T22 for the device 4-2, registered information regarding the hierarchically successive failures (6) to (8) is hierarchically arranged. In the factor table T2N for a device 4-N, registered information regarding the hierarchically successive failures (9) to (11) is hierarchically arranged.

The registered information regarding the failures (1) to (11) in the factor tables T10 and T21 to T2N illustrated in FIG. 5 includes 1) suspected portion, 2) details of failure, and 3) failure holding register information (address and bit information). Here, 1) suspected portion and 2) details of failure are the same as those described above with reference to FIG. 12, and accordingly description thereof is omitted. In the registered information illustrated in FIG. 5, “failure holding register information (address and bit information)” is included instead of “alarm number” illustrated in FIG. 12. “Failure holding register information (address and bit information)” is addresses and bit information with which the bits 21a to 21h of the failure holding register 21 corresponding to the failures (1) to (8), respectively, can be identified. In FIG. 6, bits of the failure holding register 21 corresponding to the failures (9) to (11) are omitted.

As illustrated in FIG. 6, the monitoring device (monitoring section) 10C according to the third embodiment monitors, as with the above-described monitoring devices 10, 10A, and 10B, the devices 4 and a power supply system for the devices 4 for failures in the information processing apparatus (computer system) 100C. The power supply system for the monitoring device 10C and the devices 4 according to the third embodiment is configured in the same manner as that according to the first embodiment, and accordingly description thereof is omitted.

The monitoring device 10C includes a holding unit 20C, the processing unit (monitoring processing unit) 30C, and the RAM (storage unit) 40C.

As with the above-described holding units 20 and 20A, the holding unit 20C includes a failure holding register 21 that receives and holds failure signals transmitted from the units 2 and 3 and the devices 4. The holding unit 20C is an example of the holding circuit.

In addition, the holding unit 20C includes OR circuits 22a, 22b-1, 22b-2, and 27, the factor holding register 23, a failure detection signal transmission valid/invalid register 25, and an AND circuit 26. The OR circuit 22a and the failure detection signal transmission valid/invalid register 25 are the same as those described above with reference to FIGS. 1 and 3, and accordingly description thereof is omitted.

The OR circuit 22b-1 sets a logical sum of the values of the bits 21c to 21e that hold the failures (3) to (5), respectively, of the DC-DC conversion unit 3-1 and the device 4-1 to the bit 23b-1 of the factor holding register 23 as “device failure-1” (a second failure). That is, if at least one of the failures (3) to (5) of the DC-DC conversion unit 3-1 and the device 4-1 occurs, “device failure-1”, which is the output of the OR circuit 22b-1, switches to 1, and the value of the bit 23b-1 of the factor holding register 23 is set to 1.

The OR circuit 22b-2 sets a logical sum of the values of the bits 21f to 21h that hold the failures (6) to (8), respectively, of the DC-DC conversion unit 3-2 and the device 4-2 to the bit 23b-2 of the factor holding register 23 as “device failure-2” (a second failure). That is, if at least one of the failures (6) to (8) of the DC-DC conversion unit 3-2 and the device 4-2 occurs, “device failure-2”, which is the output of the OR circuit 22b-2, switches to 1, and the value of the bit 23b-2 of the factor holding register 23 is set to 1.

The AND circuit 26 outputs a logical multiplication of the values of the bits 23b-1 and 23b-2 of the factor holding register 23 and the value of the failure detection signal transmission valid/invalid register 25.

As in the second embodiment, the failure detection signal transmission valid/invalid register 25 and the AND circuit 26 function as a switching unit that switches the permitted/suppressed state of the transmission operation for transmitting a signal indicating that the holding unit 20C has held “device failure-1” or “device failure-2” from the holding unit 20C to the processing unit 30C.

The OR circuit 27 regularly, or in accordance with an interrupt signal, generates a logical sum of the value of bit 23a of the factor holding register 23 and the value from the AND circuit 26 as a failure detection signal and transmits the failure detection signal to the processing unit 30C. That is, if 0 is set to the failure detection signal transmission valid/invalid register 25, the OR circuit 27 transmits a failure detection signal regarding “AC-DC_unit failure” to the processing unit 30C, but does not transmit a failure detection signal regarding “device failure-1” or “device failure-2”, which is “other failures”, to the processing unit 30C. On the other hand, if 1 is set to the failure detection signal transmission valid/invalid register 25, the OR circuit 27 transmits both a failure detection signal regarding “AC-DC_unit failure” and a failure detection signal regarding “device failure-1” or “device failure-2” to the processing unit 30C.

The processing unit 30C identifies, in accordance with steps S41 to S58, which will be described later, the unit 2 or 3 or the device 4 in which a failure has occurred on the basis of a failure held by the holding unit 20C and the factor tables T10 and T21 to T2N (refer to FIG. 5) held by the table region 42 of the RAM 40C.

The processing unit 30C includes a suspected portion identification timer 31 that is the same as those according to the first and second embodiments.

Upon receiving a failure detection signal, that is, a signal indicating that the holding unit 20C has held at least one of “AC-DC_unit failure”, “device failure-1”, and “device failure-2”, from the holding unit 20C, the processing unit 30C activates the timer 31, and updates the value of the failure detection signal transmission valid/invalid register 25 from 1 to 0. The transmission operation for transmitting a signal indicating that the holding unit 20C has held “device failure-1” or “device failure-2” from the holding unit 20C to the processing unit 30C is suppressed while the value of the failure detection signal transmission valid/invalid register 25 is 0.

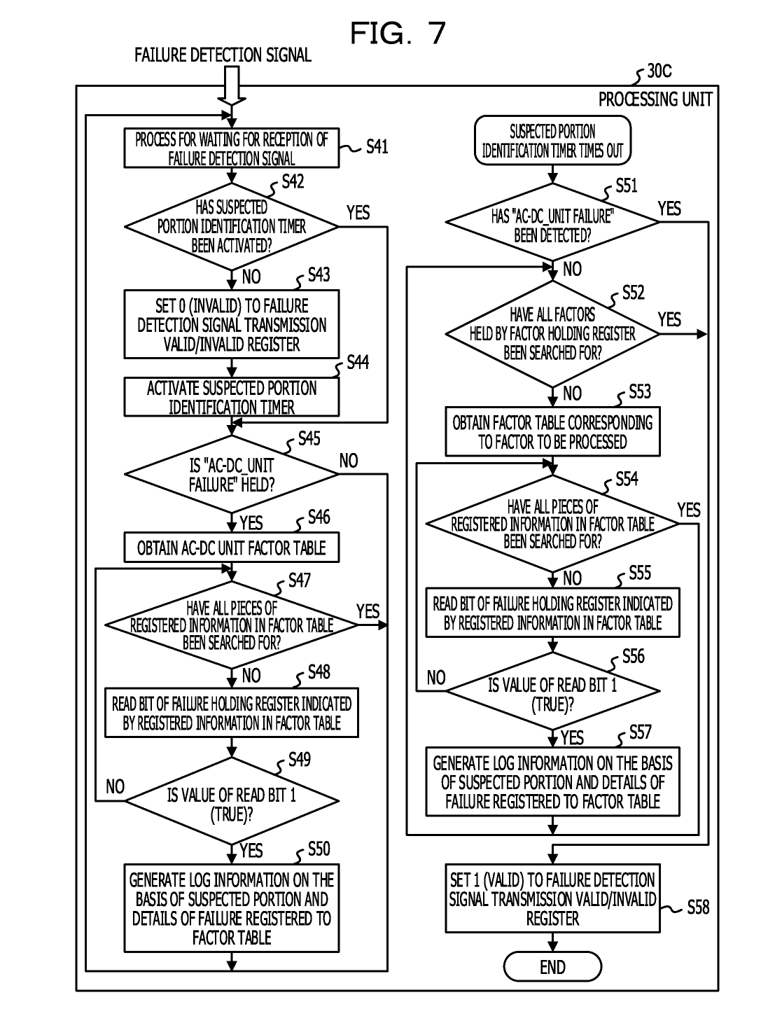

The processing unit 30C searches the bits 21a and 21b, which relate to “AC-DC_unit failure”, of the failure holding register 21 and performs a process for identifying a suspected portion (first suspected portion) in which “AC-DC_unit failure” has occurred until the certain period of time has elapsed since the timer 31 was activated. In the process, the processing unit 30C obtains the factor table T10 from the RAM 40C, and searches the bits 21a and 21b of the failure holding register 21 for failures sequentially from higher levels defined in the factor table T10, in order to identify the first suspected portion (refer to steps S46 to S50 illustrated in FIG. 7).

Since the transmission operation for transmitting a signal indicating that the holding unit 20C has held “device failure-1” or “device failure-2” from the holding unit 20C to the processing unit 30C is suppressed for the period, the processing unit 30C does not perform a process for identifying a suspected portion (second suspected portion) in which “device failure-1” or “device failure-2” has occurred. That is, during the period, the processing unit 30C gives priority to “AC-DC_unit failure” over “device failure-1” and “device failure-2”, and identifies a suspected portion in which “AC-DC_unit failure” has occurred.

On the other hand, if the suspected portion of “AC-DC_unit failure” has not been identified when the timer 31 has measured the certain period of time, the processing unit 30C performs the process for identifying a suspected portion in which “device failure-1” or “device failure-2” has occurred. In the process, the processing unit 30C obtains a factor table corresponding to a factor found in the factor holding register 23 from among the factor tables T21 to T2N. The processing unit 30C then searches the bits 21c to 21e or the bits 21f to 21h of the failure holding register 21 for failures sequentially from higher levels defined in the obtained factor table, in order to identify the second suspected portion (refer to steps S52 to S57 illustrated in FIG. 7).

After identifying the second suspected portion, the processing unit 30C updates the value of the failure detection signal transmission valid/invalid register 25 from 0 to 1. In doing so, the transmission operation for transmitting a signal indicating that the holding unit 20C has held “device failure-1” or “device failure-2” from the holding unit 20C to the processing unit 30C is permitted. If the suspected portion of “AC-DC_unit failure” has been identified when the timer 31 has measured the certain period of time, the processing unit 30C updates the value of the failure detection signal transmission valid/invalid register 25 from 0 to 1 without performing the process for identifying a suspected portion in which “device failure-1” or “device failure-2” has occurred.

[4-2] Operation According To Third Embodiment

Next, the process for identifying a suspected portion (monitoring processing procedure) executed by the processing unit 30C after the processing unit 30C receives a failure detection signal from the holding unit 20C will be described in detail with reference to a flowchart (steps S41 to S58) of FIG. 7.

In the initial state of the monitoring device 10C, 0 is set to the bits 21a to 21h of the failure holding register 21 and the bits 23a, 23b-1, and 23b-2 of the factor holding register 23, and 1 is set to the failure detection signal transmission valid/invalid register 25. The timer 31 that measures a period of time (the above-described period of time) in which the suspected portion is identified has not been activated. All log information in a log region 41 of the RAM 40C has been deleted.

The processing unit 30C continuously waits for a signal transmitted from the holding unit 20C (step S41).

If the suspected portion identification timer 31 has not been activated (NO in step S42) when the processing unit 30C has received a failure detection signal from the holding unit 20C for the first time, the processing unit 30C performs the following process. That is, the processing unit 30C updates the value of the failure detection signal transmission valid/invalid register 25 from 1 to 0, and suppresses the transmission operation for transmitting a failure detection signal regarding “device failure-1” or “device failure-2”, which is “other failures”, from the holding unit 20C to the processing unit 30C (step S43). In addition, the processing unit 30C activates the timer 31 (step S44). Thereafter, the processing unit 30C proceeds to processing in step S45. If the timer 31 has already been activated (YES in step S42), the processing unit 30C proceeds to the processing in step S45 without performing the processing in steps S43 and S44. The order in which steps S43 and S44 are executed may be reversed.

The processing unit 30C refers to the bits 23a of the factor holding register 23 of the holding unit 20C, and if 1 is set to the bit 23a, the processing unit 30C determines that the holding unit 20C holds “AC-DC_unit failure” (the YES route in step S45). In this case, the processing unit 30C obtains the factor table T10, which corresponds to “AC-DC_unit failure” (failures (1) and (2)), from the RAM 40C (steps 46). The processing unit 30C then searches the bits 21a and 21b of the failure holding register 21 for failures sequentially from higher levels defined in the factor table T10 in accordance with steps S45 to S50, which will be described later, in order to identify the first suspected portion.

That is, the processing unit 30C searches for each piece of registered information in the factor table T10 from higher levels to lower levels (NO in step S47), and refers to the failure holding register information of found registered information. The processing unit 30C then reads the value of a bit of the failure holding register 21 identified from the failure holding register information that has been referred to (step S48).

If the read value is 0 (false) (NO in step S49), the processing unit 30C returns to the processing in step S47. The processing unit 30C searches the factor table T10 for registered information at a next lower level (NO in step S47), and executes steps S48 and S49. For example, in the case of the factor table T10 illustrated in FIG. 5, first, the value of the bit 21a corresponding to the failure (1) is read, and then the value of the bit 21b corresponding to the failure (2) is read.

After searching for all the registered information in the factor table T10 (YES in step S47), the processing unit 30C returns to the waiting process in step S41. At this time, the processing unit 30C waits for a failure detection signal from an AC-DC conversion unit, which is not illustrated in FIGS. 5 and 6, other than the AC-DC conversion unit 2.

If the value read in step S48 is 1 (true) (YES in step S49), the processing unit 30C generates new log information in the log region 41 of the RAM 40C (step S50). The log information is generated on the basis of the suspected portion and the details of the failure registered to the registered information in the factor table T10. Thereafter, the processing unit 30C returns to the waiting process in step S41, and waits for a failure detection signal from an AC-DC conversion unit, which is not illustrated in FIGS. 5 and 6, other than the AC-DC conversion unit 2.

When the certain period of time has elapsed and the suspected portion identification timer 31 has timed out while the above-described process (steps S41 to S50) is being repeatedly executed, the processing unit 30C proceeds to processing in step S51. In step S51, the processing unit 30C refers to the log region 41 of the RAM 40C, and determines whether or not “AC-DC_unit failure” has been detected.

If “AC-DC_unit failure” has been detected (YES in step S51), the suspected portion of “AC-DC_unit failure” has already been identified, and log information regarding “AC-DC_unit failure” that has been detected during the certain period of time is saved in the log region 41. Therefore, the processing unit 30C updates the value of the failure detection signal transmission valid/invalid register 25 from 0 to 1 without performing the process for identifying the suspected portion of “device failure-1” or “device failure-2” (step S58). In doing so, the processing unit 30C permits the transmission operation for transmitting a failure detection signal regarding “device failure-1” or “device failure-2” from the holding unit 20C to the processing unit 30C, and ends the process.

On the other hand, if “AC-DC_unit failure” has not been detected (NO in step S51), the processing unit 30C performs the process for identifying a suspected portion in which “other failures”, that is, “device failure-1” or “device failure-2”, has occurred. In this case, the processing unit 30C searches for each factor (that is, the bits 23b-1 and 23b-2) held by the factor holding register 23 (NO in step S52), and obtains a factor table corresponding to a found factor from the RAM 40C (step S53). For example, if 1 is set to the searched bit 23b-1, the factor table T21 is obtained, and if 1 is set to the searched bit 23b-2, the factor table T22 is obtained.

The processing unit 30C searches each piece of registered information in the searched factor table from higher levels to lower levels (NO in step S54), and refers to failure holding register information in found registered information. The processing unit 30C then reads the value of a bit of the failure holding register 21 identified by the failure holding register information that has been referred to (step S55).

If the read value is 0 (false) (NO in step S56), the processing unit 30C returns to step S54. The processing unit 30C searches the factor table for registered information at a next lower level (NO in step S54), and executes steps S55 and S56. For example, in the case of the factor table T21 illustrated in FIG. 5, first, the value of the bit 21c corresponding to the failure (3) is read, and then the value of the bit 21d corresponding to the failure (4) is read. Finally, the value of the bit 21e corresponding to the failure (5) is read.

After searching all the registered information in the factor table (YES in step S54), the processing unit 30C returns to the processing in step S52.

If the value read in step S55 is 1 (true) (YES in step S56), the processing unit 30C generates new log information in the log region 41 of the RAM 40C (step S57). The log information is generated on the basis of the suspected portion and the details of the failure registered to the registered information in the factor table. Thereafter, the processing unit 30C returns to the waiting process in step S52.

After searching all the factors (that is, the bits 23b-1 and 23b-2) held by the factor holding register 23 (YES in step S52), the processing unit 30C updates the value of the failure detection signal transmission valid/invalid register 25 from 0 to 1 (step S58). In doing so, the processing unit 30C permits the transmission operation for transmitting a failure detection signal regarding “device failure-1” or “device failure-2” from the holding unit 20C to the processing unit 30C, and ends the process.

According to the monitoring device 10C (processing unit 30C) according to the third embodiment, the same function effects as those in the first and second embodiments may be produced.

As described above, the processing unit 30C according to the third embodiment is configured in such a way as to be able to identify a suspected portion by searching the suspected portion identification table (factor table) for the registered information from higher levels to lower levels. By this configuration, when the value of a bit of the failure holding register 21 identified from the failure holding register information in each piece of registered information in the factor table is 1 (true), the processing unit 30C completes the identification of a suspected portion at the highest level. Therefore, the processing unit 30C does not search for registered information at all the levels of the factor table. Accordingly, even if a large number of “other failures” occur, a load on the processing unit 30C caused by the process for identifying a suspected portion does not become large, and the monitoring device 10C may continue a stable operation.

Furthermore, when, in the process for identifying a suspected portion performed by the processing unit 30 illustrated in FIGS. 10 and 11, the numbers of AC-DC conversion units 2, DC-DC conversion units 3, and devices 4 have increased, the number of unique alarm numbers provided for the AC-DC conversion units 2, the DC-DC conversion units 3, and the devices 4 and the number of hierarchical tables also increase. Accordingly, the load on the processing unit 30 caused by the process for determining the level of a failure, that is, the process for identifying a suspected portion, becomes large. In contrast, according to the processing unit 30C according to the third embodiment, an alarm number is not provided and the level of a failure is not determined, and therefore a suspected portion of the power supply system in which a failure has occurred may be easily identified while suppressing the load caused by the process for identifying a suspected portion.

Depending on the structure of the computer system, there may be a suspected portion in which “AC-DC_unit failure” is not detected but a large number of “other failures” occur (disconnection or breaking of a power supply cable of the AC-DC conversion unit 2). If a failure occurs in such a suspected portion, the load caused by the process for identifying a suspected portion after the suspected portion identification timer 31 times out becomes significantly large. On the other hand, according to the processing unit 30C according to the third embodiment, the level of the failure is not determined, and therefore the load caused by the process for identifying a suspected portion may be suppressed.

### [5] Fourth Embodiment

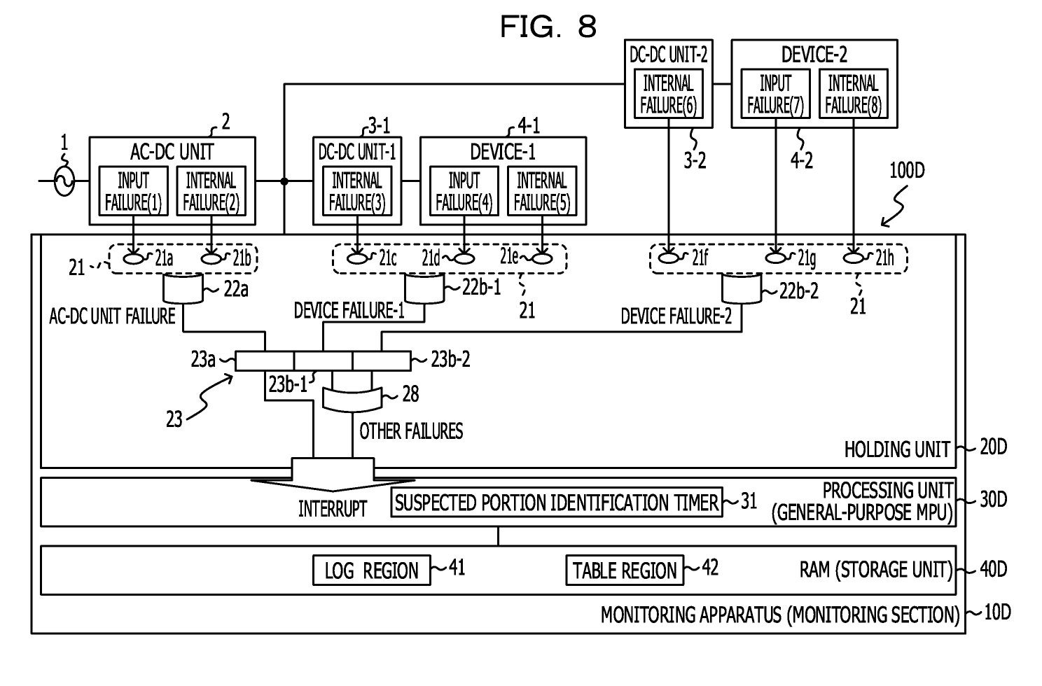

The configuration of an information processing apparatus 100D including a monitoring device 10D according to a fourth embodiment will be described hereinafter with reference to FIG. 8. FIG. 8 is a block diagram illustrating the configuration of the information processing apparatus 100D including the monitoring device 10D according to the fourth embodiment. Because the same reference numerals as those mentioned above denote the same or substantially the same components, detailed description of such components is omitted.

As illustrated in FIG. 8, the monitoring device (monitoring section) 10D according to the fourth embodiment monitors, as with the above-described monitoring devices 10 and 10A to 10C, devices 4 and a power supply system for the devices 4 for failures in the information processing apparatus (computer system) 100D. The power supply system for the monitoring device 10D and the devices 4 according to the fourth embodiment is configured in the same manner as those according to the first and third embodiments, and accordingly description thereof is omitted.

The monitoring device 10D includes a holding unit 20D, a processing unit (monitoring processing unit) 30D, and a RAM (storage unit) 40D.

The monitoring device 10D according to the fourth embodiment is configured in such a way as to realize the same function as that of the monitoring device 10C according to the third embodiment using the processing unit 30D, which is a general-purpose microprocessing unit (MPU) and perform the process for identifying a suspected portion using an interrupt function of the general-purpose MPU 30D. The factor tables T10 and T21 to T2N described above with reference to FIG. 5 are saved to a table region 42 of the RAM 40D in advance.

As with the above-described holding units 20, 20A, and 20C, the holding unit 20D includes a failure holding register 21 that receives and holds failure signals transmitted from units 2 and 3 and the devices 4. The holding unit 20D is an example of the holding circuit.

In addition, the holding unit 20D includes OR circuits 22a, 22b-1, 22b-2, and 28 and a factor holding register 23.

The OR circuit 22a sets a logical sum of the values of the two bits 21a and 21b that hold the failures (1) and (2), respectively, of the AC-DC conversion unit 2 to the bit 23a of the factor holding register 23 as “AC-DC_unit failure”. That is, if at least either the failure (1) or (2) of the AC-DC conversion unit 2 occurs, “AC-DC_unit failure”, which is the output of the OR circuit 22a, switches to 1, and the value of the bit 23a of the factor holding register 23 is set to 1. The value of the bit 23a of the factor holding register 23 is transmitted to the general-purpose MPU 30D as a failure detection signal indicating “AC-DC_unit failure” (a first failure).

The OR circuit 22b-1 sets a logical sum of the values of the bits 21c to 21e that hold the failures (3) to (5), respectively, of the DC-DC conversion unit 3-1 and the device 4-1 to the bit 23b-1 of the factor holding register 23 as “device failure-1”. That is, if at least one of the failures (3) to (5) of the DC-DC conversion unit 3-1 and the device 4-1 occurs, “device failure-1”, which is the output of the OR circuit 22b-1, switches to 1, and the value of the bit 23b-1 of the factor holding register 23 is set to 1.

The OR circuit 22b-2 sets a logical sum of the values of the bits 21f to 21h that hold the failures (6) to (8), respectively, of the DC-DC conversion unit 3-2 and the device 4-2 to the bit 23b-2 of the factor holding register 23 as “device failure-2”. That is, if at least one of the failures (6) to (8) of the DC-DC conversion unit 3-2 and the device 4-2 occurs, “device failure-2”, which is the output of the OR circuit 22b-2, switches to 1, and the value of the bit 23b-2 of the factor holding register 23 is set to 1.

The OR circuit 28 transmits a logical sum of the values of the bits 23b-1 and 23b-2 of the factor holding register 23 to the general-purpose MPU 30D as “other failures” (a detection signal regarding a second failure).

In the third embodiment, the function of the switching unit that switches the permitted/suppressed state of the transmission operation for transmitting “other failures (device failure-1 or device failure-2)” from the holding unit 20C to the processing unit 30C is realized by the failure detection signal transmission valid/invalid register 25 and the AND circuit 26. In the fourth embodiment, the function of the switching unit is realized by a function of validating/invalidating an interrupt by “other failures” (a failure detection signal) from the OR circuit 28 on the general-purpose MPU 30D side. For example, the general-purpose MPU 30D permits the transmission operation by setting “valid (1)” to a certain MPU register to validate an interrupt by “other failures”. On the other hand, the general-purpose MPU 30D suppresses the transmission operation by setting “invalid (0)” to the certain MPU register to invalidate an interrupt by “other failures”.

The general-purpose MPU 30D identifies, in accordance with steps S61 to S69, which will be described later, the unit 2 or 3 or the device 4 in which a failure has occurred on the basis of a failure held by the holding unit 20D and the factor tables T10 and T21 to T2N (refer to FIG. 5) held by the table region 42 of the RAM 40D.

The general-purpose MPU 30D includes a suspected portion identification timer 31 that is the same as those according to the first to third embodiments.

Upon receiving a failure detection signal, that is, a signal indicating that the holding unit 20D has held “AC-DC_unit failure” or “other failures”, from the holding unit 20D, the processing unit 30D activates an interrupt process using “AC-DC_unit failure” or an interrupt process using “other failures”. When an interrupt process has been activated, the timer 31 is activated and “invalid” is set to the certain MPU register.

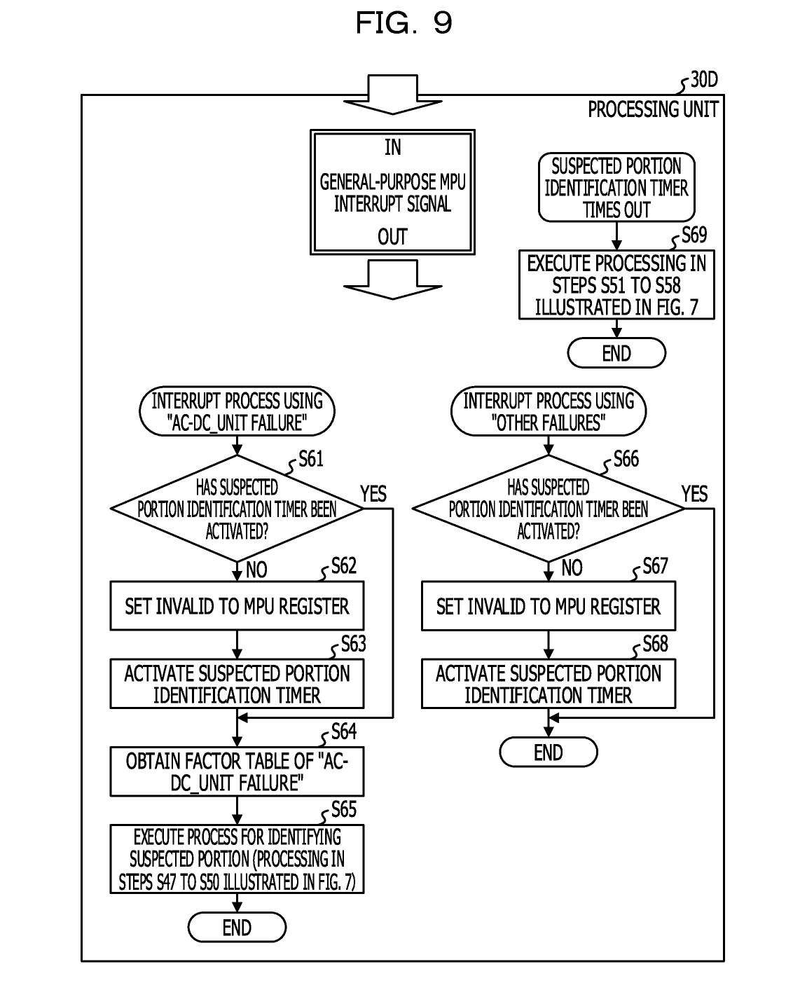

If the interrupt process using “AC-DC_unit failure” is activated, the general-purpose MPU 30D searches the bits 21a and 21b, which relate to “AC-DC_unit failure”, of the failure holding register 21 and performs a process for identifying a suspected portion (first suspected portion) in which “AC-DC_unit failure” has occurred until the timer 31 has measured the certain period of time. In the process, the general-purpose MPU 30D obtains the factor table T10 from the RAM 40D, and searches the bits 21a and 21b of the failure holding register 21 for failures sequentially from higher levels defined in the factor table T10, in order to identify the first suspected portion (refer to steps S64 and S65 illustrated in FIG. 9).

If the interrupt process using “other failures” is activated, the general-purpose MPU 30D only activates the timer 31 and sets “invalid” to the certain MPU register, and does not perform a process for identifying the suspected portion of “other failures” during the certain period of time. That is, in the certain period of time, the general-purpose MPU 30D gives priority to “AC-DC_unit failure” over “other failures”, and identifies a suspected portion in which “AC-DC_unit failure” has occurred.

On the other hand, if the suspected portion of “AC-DC_unit failure” has not been identified when the timer 31 has measured the certain period of time, the general-purpose MPU 30D performs, as with the processing unit 30C according to the third embodiment, a process for identifying a suspected portion (second suspected portion) in which “other failures” has occurred.

After identifying the second suspected portion, the general-purpose MPU 30D sets “valid” to the certain MPU register. In doing so, an interrupt using a signal indicating that the holding unit 20D has held “other failures” becomes valid in the general-purpose MPU 30D. That is, a transmission operation for transmitting the signal from the holding unit 20D to the general-purpose MPU 30D is permitted. On the other hand, if the suspected portion of “AC-DC_unit failure” has been identified when the timer 31 has measured the certain period of time, the general-purpose MPU 30D sets “valid” to the certain MPU register without performing the process for identifying a suspected portion in which “other failures” has occurred.

[5-2] Operation According to Fourth Embodiment

Next, the interrupt process executed by the general-purpose MPU 30D after the general-purpose MPU 30D receives a failure detection signal from the holding unit 20D will be described in detail with reference to a flowchart (steps S61 to S69) of FIG. 9.

In the initial state of the monitoring device 10D, 0 is set to the bits 21a to 21h of the failure holding register 21 and the bits 23a, 23b-1, and 23b-2 of the factor holding register 23, and “valid” is set to the certain MPU register. The timer 31 that measures a period of time (the above-described period of time) in which the suspected portion is identified has not been activated. All log information in a log region 41 of the RAM 40D has been deleted.

When “AC-DC_unit failure” has been received from the holding unit 20D for the first time after the initial setting, the general-purpose MPU 30D activates the interrupt process using “AC-DC_unit failure”, and, if the suspected portion identification timer 31 has not been activated (NO in step S61), executes the following process. That is, the general-purpose MPU 30D sets “invalid” to the certain MPU register, so that the interrupt process is not activated even if “other failures” is received thereafter (step S62). In addition, the general-purpose MPU 30D activates the timer 31 (step S63). Thereafter, the general-purpose MPU 30D proceeds processing in step S64. If the timer 31 has already been activated (YES in step S61), the general-purpose MPU 30D proceeds to the processing in step S64 without performing the processing in steps S62 and S63. The order in which steps S62 and S63 are executed may be reversed.

On the other hand, when “other failures” has been received from the holding unit 20D for the first time after the initial setting, the general-purpose MPU 30D activates the interrupt process using “other failures”, and, if the suspected portion identification timer 31 has not been activated (NO in step S66), sets “valid” to the certain MPU register, so that the interrupt process is not activated even if “other failures” is received thereafter (step S67). In addition, the general-purpose MPU 30D activates the timer 31 (step S68). Thereafter, the general-purpose MPU 30D ends the interrupt process using “other failures”. The order in which steps S67 and S68 are executed may be reversed.

In step S64 of the interrupt process of “AC-DC_unit failure”, the general-purpose MPU 30D obtains the factor table T10 corresponding to “AC-DC_unit failure” (failures (1) and (2)) from the RAM 40D. The general-purpose MPU 30D then searches the bits 21a and 21b of the failure holding register 21 for failures sequentially from higher levels defined in the factor table T10 and identifies the first suspected portion (step S65), and then ends the interrupt process using “AC-DC_unit failure”. The process for identifying the first suspected portion executed in step S65 is the same as the above-described process executed in steps S47 to S50 illustrated in FIG. 11, and accordingly description thereof is omitted.

When the certain period of time has elapsed and the suspected portion identification timer 31 has timed out, the general-purpose MPU 30D proceeds to processing in step S69. The processing executed in step S69 is the same as the above-described processing executed in steps S51 to S58, and accordingly description thereof is omitted.

According to the monitoring device 10D (general-purpose MPU 30D) according to the fourth embodiment, the same function effects as those according to the third embodiment may be produced.

In addition, in the fourth embodiment, the interrupt process activated by “AC-DC_unit failure” and the interrupt process activated by “other failures” are registered to the general-purpose MPU 30D. Therefore, the general-purpose MPU 30D does not regularly monitor for a failure detection signal, and may perform only parts of the interrupt processes activated by “AC-DC_unit failure” and “other failures”, respectively, to be used. Therefore, the process for identifying a suspected portion of the power supply system may be executed by a minimum operation.

### [6] Other Embodiments

Although the preferable embodiments have been described in detail above, the embodiments disclosed herein are not limited to these particular embodiments, and may be implemented by modifying and altering such embodiments in various ways without deviating the scope of the embodiments disclosed herein.

Although a case in which “AC-DC_unit failure” has four types, namely the failures (1), (2), (1)′ and (2)′, and “other failures” has nine types, namely the failures (3) to (11), has been described in the above embodiments, the embodiments disclosed herein is not limited to these numbers. Similarly, the numbers of AC-DC conversion units 2, DC-DC conversion units 3, and devices 4 in the embodiments disclosed herein are not limited to the numbers of AC-DC conversion units 2, DC-DC conversion units 3, and devices 4 mounted in the above embodiments.

The value (default value) of the certain period of time measured by the suspected portion identification timer 31 in the above embodiments is different depending on the configurations (devices, power supplies used, and the like) of the computer system 100 and 100A to 100D. Therefore, the processing units 30 and 30A to 30D each include a suspected portion identification timer, and activate a timer according to each of the configurations of the computer systems 100 and 100A to 100D, respectively.

The entirety or a part of the function of each of the above-described processing units 30 and 30A to 30D may be realized by executing a certain application program (monitoring program) using the function of a computer (central processing unit (CPU) or the like) in each of the monitoring devices 10 and 10A to 10D, respectively.

The program may be recorded on a computer-readable recording medium such as, for example, a flexible disk, a compact disc (CD) (compact disc read-only memory (CD-ROM), a compact disc-recordable (CD-R), a compact disc-rewritable (CD-RW), or the like), a digital versatile disc (DVD) (digital versatile disc read-only memory (DVD-ROM), digital versatile disk random-access memory (DVD-RAM), digital versatile disc-recordable (DVD-R), digital versatile disc-rewritable (DVD-RW), DVD+R, DVD+RW, or the like), or a Blu-ray Disc (registered trademark), and provided. In this case, the computer reads the program from the recording medium and uses the program by transferring the program to an internal storage device or an external storage device and by storing the program.

Here, the computer refers to hardware that operates under control of an operating system (OS). When the OS is not used and hardware is operated only by the application program, the hardware itself corresponds to the computer. The hardware includes at least a microprocessor such as a CPU and a unit for reading the computer program recorded on the recording medium. The monitoring program includes a program code for causing the above-described computer to realize the entirety or a part of the function of each of the above-described monitoring processing unit 30 and 30A to 30D. A part of the function may be realized not by the application program but by the OS.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A monitoring device comprising:
a holding circuit; and
a processor configured to give priority to a first failure over a second failure when the holding circuit holds the first failure and identify a first suspected portion in which the first failure has occurred,
wherein the first failure is a failure detected in a first power supply unit and the second failure is a failure detected at least either in a device or in a second power supply unit that converts power supplied from the first power supply unit and that supplies resultant power to the device.

2. The monitoring device according to claim 1, further comprising:
a timer configured to measure a certain period of time assumed to be taken until the holding circuit holds failures relating to a certain failure after holding the certain failure,
wherein, upon receiving a signal indicating that the holding circuit has held the first failure or the second failure, the processor is configured to activate the timer, and
wherein, until the certain period of time is measured after the timer is activated, the processor is configured to give priority to the first failure over the second failure and to identify the first suspected portion in which the first failure has occurred.

3. The monitoring device according to claim 1,
wherein, when the holding circuit does not hold the first failure and holds the second failure, the processor is configured to identify a second suspected portion in which the second failure has occurred.

4. The monitoring device according to claim 1, further comprising:
a timer configured to measure a certain period of time assumed to be taken until the holding circuit holds failures relating to a certain failure after holding the certain failure; and
a switching circuit configured to switch a permitted or suppressed state of a transmission operation for transmitting a signal indicating that the holding circuit has held the second failure from the holding circuit to the processor,
wherein, upon receiving a signal indicating that the holding circuit has held the first failure or the second failure, the processor is configured to activate the timer and to cause the switching circuit to switch the transmission operation to a suppressed state, and
wherein, until the certain period of time is measured after the timer is activated, the processor is configured to give priority to the first failure over the second failure and to identify the first suspected portion in which the first failure has occurred.

5. The monitoring device according to claim 4,
wherein, when the first suspected portion has not been identified when the timer has measured the certain period of time, the processor is configured to search for the second failure held by the holding circuit and to identify a second suspected portion in which the found second failure has occurred, and then to cause the switching circuit to switch the transmission operation to a permitted state, and
wherein, when the first suspected portion has been identified when the timer has measured the certain period of time, the processor is configured to cause the switching circuit to switch the transmission operation to the permitted state without identifying the second suspected portion.

6. The monitoring device according to claim 3, further comprising:
a storage configured to save information that hierarchically defines information regarding failures relating to the first failure and the second failure,
wherein the processor is configured to identify the first suspected portion or the second suspected portion on the basis of the information.

7. The monitoring device according to claim 5, further comprising:
a storage configured to save first information that hierarchically defines information regarding failures relating to the first failure and second information that hierarchically defines information regarding failures relating to the second failure,
wherein the processor is configured to search the holding circuit for failures sequentially from higher levels defined in the first information and to identify the first suspected portion, and
wherein the processor is configured to search the holding circuit for failures sequentially from higher levels defined in the second information and to identify the second suspected portion.

8. An information processing apparatus comprising:
a device;
a first power supply unit;
a second power supply unit configured to convert power supplied from the first power supply unit and supply resultant power to the device;
a processor configured to monitor the device, the first power supply unit, and the second power supply; and
a holding circuit,
wherein, when the holding circuit holds a first failure, the processor is configured to give priority to the first failure over a second failure, and to identify a first suspected portion in which the first failure has occurred, the first failure being a failure detected in the first power supply unit, the second failure being a failure detected at least either in the device or in the second power supply unit that converts power supplied from the first power supply unit and that supplies resultant power to the device.

9. The information processing apparatus according to claim 8, further comprising:
a timer configured to measure a certain period of time assumed to be taken until the holding circuit holds failures relating to a certain failure after holding the certain failure,
wherein, upon receiving a signal indicating that the holding circuit has held the first failure or the second failure, the processor is configured to activate the timer, and
wherein, until the certain period of time is measured after the timer is activated, the processor is configured to give priority to the first failure over the second failure and to identify the first suspected portion in which the first failure has occurred.

10. The information processing apparatus according to claim 8,
wherein, when the holding circuit does not hold the first failure and holds the second failure, the processor is configured to identify a second suspected portion in which the second failure has occurred.

11. The information processing apparatus according to claim 8, further comprising:
a timer configured to measure a certain period of time assumed to be taken until the holding circuit holds failures relating to a certain failure after holding the certain failure; and
a switching circuit configured to switch a permitted or suppressed state of a transmission operation for transmitting a signal indicating that the holding circuit has held the second failure from the holding circuit to the processor,
wherein, upon receiving a signal indicating that the holding circuit has held the first failure or the second failure, the processor is configured to activate the timer and to cause the switching circuit to switch the transmission operation to a suppressed state, and
wherein, until the certain period of time is measured after the timer is activated, the processor is configured to give priority to the first failure over the second failure and to identify the first suspected portion in which the first failure has occurred.

12. The information processing apparatus according to claim 11,
wherein, when the first suspected portion has not been identified when the timer has measured the certain period of time, the processor is configured to search for the second failure held by the holding circuit and to identify a second suspected portion in which the found second failure has occurred, and then to cause the switching circuit to switch the transmission operation to a permitted state, and
wherein, when the first suspected portion has been identified when the timer has measured the certain period of time, the processor is configured to cause the switching circuit to switch the transmission operation to the permitted state without identifying the second suspected portion.

13. The information processing apparatus according to claim 10, further comprising:
a storage configured to save information that hierarchically defines information regarding failures relating to the first failure and the second failure,
wherein the processor is configured to identify the first suspected portion or the second suspected portion on the basis of the information.

14. The information processing apparatus according to claim 12, further comprising:
a storage configured to save first information that hierarchically defines information regarding failures relating to the first failure and second information that hierarchically defines information regarding failures relating to the second failure,
wherein the processor is configured to search the holding circuit for failures sequentially from higher levels defined in the first information and to identify the first suspected portion, and
wherein the processor is configured to search the holding circuit for failures sequentially from higher levels defined in the second information and to identify the second suspected portion.

15. A monitoring method comprising:
giving, when a holding circuit holds a first failure, priority to a first failure over a second failure and identifying a first suspected portion in which the first failure has occurred, the first failure being a failure detected in a first power supply unit, the second failure being a failure detected at least either in a device or in a second power supply unit that converts power supplied from the first power supply unit and that supplies resultant power to the device.

16. The monitoring method according to claim 15, further comprising:
receiving a signal indicating that the holding circuit has held the first failure or the second failure;
activating a timer that measures a certain period of time assumed to be taken until the holding circuit holds failures relating to a certain failure after holding the certain failure; and
giving, until the certain period of time is measured after the timer is activated, priority to the first failure over the second failure and identifying the first suspected portion in which the first failure has occurred.

17. The monitoring method according to claim 15, further comprising:
receiving a signal indicating that the holding circuit has held the first failure or the second failure;
activating a timer that measures a certain period of time assumed to be taken until the holding circuit holds failures relating to a certain failure after holding the certain failure;
setting a transmission operation for transmitting a signal indicating that the holding circuit has held the second failure to a suppressed state; and
giving, until the certain period of time is measured after the timer is activated, priority to the first failure over the second failure and identifying the first suspected portion in which the first failure has occurred.

18. The monitoring method according to claim 17, further comprising:
searching, when the first suspected portion has not been identified when the timer has measured the certain period of time, for the second failure held by the holding circuit and identifying a second suspected portion in which the found second failure has occurred, and then setting the transmission operation to a permitted state, and
setting, when the first suspected portion has been identified when the timer has measured the certain period of time, the transmission operation to the permitted state without identifying the second suspected portion.

19. The monitoring method according to claim 18, further comprising;
searching the holding circuit for failures sequentially from higher levels defined in first information that hierarchically defines information regarding failures relating to the first failure and identifying the first suspected portion, and
searching the holding circuit for failures sequentially from higher levels defined in second information that hierarchically defines information regarding failures relating to the second failure and identifying the second suspected portion.
